(19) United States
(12) Patent Application Publication
(10) Pub. No.: US 2026/0117059 A1
(43) Pub. Date: Apr. 30, 2026

(54) CURABLE RESIN, CURABLE RESIN COMPOSITION, CURED PRODUCT, PREPREG, LAMINATE, AND SEMICONDUCTOR SUBSTRATE

(71) Applicant: NIPPON KAYAKU KABUSHIKI KAISHA, Tokyo (JP)

(72) Inventors: Atsuhiko HASEGAWA, Tokyo (JP); Masanori HASHIMOTO, Tokyo (JP); Risa HONDA, Tokyo (JP)

(73) Assignee: NIPPON KAYAKU KABUSHIKI KAISHA, Tokyo (JP)

(21) Appl. No.: 19/165,017

(22) PCT Filed: Mar. 11, 2024
(86) PCT No.: PCT/JP2024/009337

§ 371 Date: Sep. 12, 2025

(30) Foreign Application Priority Data
Mar. 14, 2023 (JP) 2023-039175

(51) Int. Cl. C08L 61/14; C08G 8/10; C08J 5/24; C08L 71/12; H10W 70/695

(52) U.S. Cl. CPC C08L 61/14; C08G 8/10; C08J 5/24; C08L 71/12; H10W 70/695; C08J 2361/14; C08J 2371/12; C08J 2461/14; C08J 2471/12; C08L 2203/20

(57) ABSTRACT

The present invention provides a curable resin having excellent dielectric properties, a curable resin composition, and cured products thereof. The present invention specifically provides a curable resin which is represented by formula (1). In formula (1), A represents any of the following formulas (1-a) to (1-d). The plurality of X each independently represent any of the following formulas (1-e) to (1-g). The plurality of R₁ each independently represent a residue obtained by removing one hydrogen atom from a C9 petroleum resin. The plurality of R₂ each independently represent a hydrogen atom, a hydrocarbon group having 1 to 10 carbon atoms, an alkoxy group having 1 to 6 carbon atoms, an amino group, or a hydroxy group. The plurality of s and t are each independently an integer of 0 to 3, and the total of s, which is the number of R₁ moieties, and t, which is the number of R₂ moieties, the moieties being bonded to the same aromatic ring, is an integer of 0 to 3. The average value of s sₐᵥₑ satisfies 0<sₐᵥₑ≤3, and the average value of t tₐᵥₑ satisfies 0≤tₐᵥₑ≤2. n is the average number of repetitions and satisfies 0.1≤n≤5.

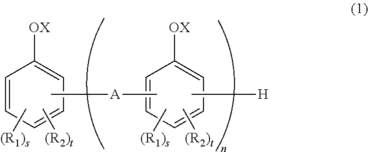

### TECHNICAL FIELD

The present invention relates to a curable resin, a curable resin composition, a cured product, a prepreg, a laminate, and a semiconductor substrate, and is suitably used for electric and electronic parts such as semiconductor encapsulation materials, printed wiring boards, and build-up laminates.

In recent years, the laminates on which electric and electronic components are mounted have come to be used in a wider range of fields, and the required characteristics have become more extensive and sophisticated. Conventional semiconductor chips were mainly mounted on metal lead frames, but semiconductor chips with high processing power, such as central processing units (hereinafter referred to as CPUs), are increasingly being mounted on laminates made of polymer materials.

The fifth generation communication system “5G”, which is currently being developed at an accelerated pace, is expected to achieve even greater capacity and faster communication speeds. Since the attenuation rate of signals flowing through the dielectric material constituting the printed wiring board is proportional to the dielectric tangent (tan δ), the need for low dielectric materials is increasing. In addition, since the attenuation of signals directly generates heat and causes a rise in temperature, a dielectric tangent of 0.005 or less is required for printed wiring boards (Non Patent Literatures 1 and 2). However, when epoxy resins are cured with phenols or amines, the reaction mechanism causes the generation of hydroxy groups during the curing reaction, which tends to deteriorate the water absorption and electrical properties.

In view of this situation, maleimide resins and polyphenylene ethers have been studied in recent years as printed wiring board materials in the high frequency range. Maleimide resins themselves have the characteristic of being highly heat resistant due to their high crosslink density. On the other hand, they have the problem of being prone to water absorption, which can easily deteriorate their properties (Patent Literature 1). In addition, Patent Document 2 discloses a polyphenylene ether oligomer having specific vinyl groups at both ends, but it is difficult to say that its dielectric properties are sufficient. Patent Literature 3 discloses a phenolic resin modified with a petroleum resin, but further improvement in the dielectric properties is required.

### CITATION LIST

### Patent Literature

Patent Literature 1: Japanese Patent Application Publication No. H04-178358
Patent Literature 2: International Publication No. 2005/73264
Patent Literature 3: Japanese Patent Application Publication No. 2020-111712

### Non Patent Literature

Non Patent Literature 1: 2021 Electronics Packaging New Materials Handbook
Non Patent Literature 2: Proceedings of the Microelectronics Symposium (Vol. 20, 2010, pp. 239-242)

### SUMMARY OF INVENTION

### Technical Problem

The present invention has been made in view of the above-mentioned points, and an object of the present invention is to provide a curable resin, a curable resin composition, and a cured product thereof, which have excellent dielectric properties.

### Solution to Problem

That is, the present invention relates to the following [1] to [14]. Note that in the present invention, “(Numerical value 1) to (Numerical value 2)” indicates that the upper and lower limits are included.

[1] A curable resin represented by the following formula (1):

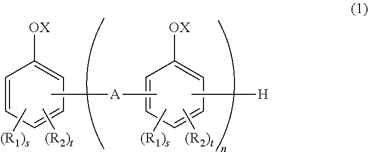

In formula (1), A represents any one of the following formulas (1-a) to (1-d). Each of the multiple Xs independently represents any one of the following formulas (1-e) to (1-g). Each of the multiple R₁s independently represents a residue obtained by removing one hydrogen atom from a C9 petroleum resin. Each of the multiple R₂s independently represents a hydrogen atom, a hydrocarbon group having 1 to 10 carbon atoms, an alkoxy group having 1 to 6 carbon atoms, an amino group, or a hydroxy group. Each of the multiple s and t independently represents an integer of 0 to 3, and the sum of s and t is an integer of 0 to 3, s is the number of R₁ bonded to the same aromatic ring, and t is the number of R₂ bonded to the same aromatic ring. The average value sₐᵥₑ of s is 0<sₐᵥₑ≤3, and the average value tₐᵥₑ of t is 0≤tₐᵥₑ≤2. n is the number of repetitions, and the average value nₐᵥₑ of n is 0.1≤nₐᵥₑ≤5.

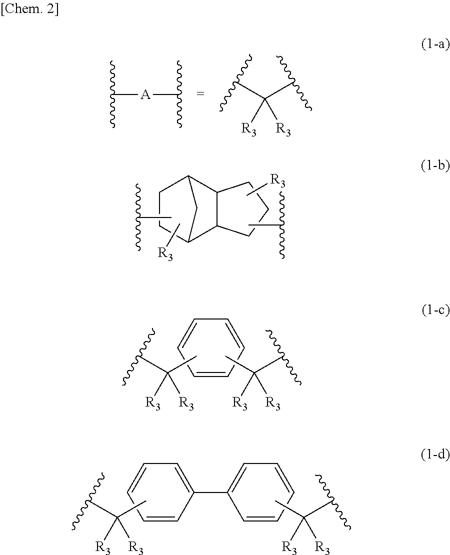

In formulas (1-a) to (1-d), each of the multiple R₃s independently represents a hydrogen atom or a hydrocarbon group having 1 to 10 carbon atoms. The wavy line represents a bonding site to the aromatic ring in formula (1).

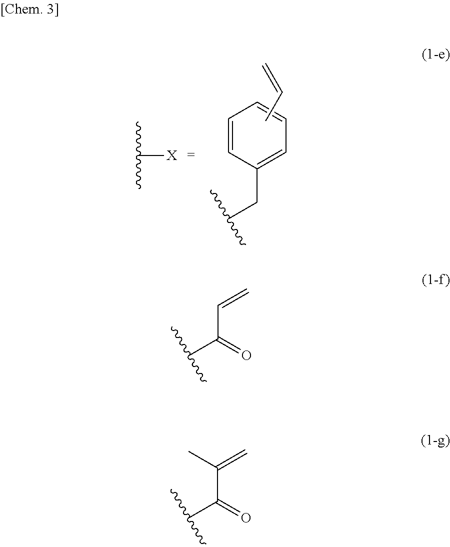

In formulas (1-e) to (1-g), the wavy lines represent the bonding sites to the oxygen atom in formula (1).

[2] A curable resin obtained by reacting a phenolic resin obtained by reacting a phenolic resin (P3) containing a C9 petroleum resin (P2) having a phenolic hydroxy group with any of the compounds represented by the following formulas (4-a) to (4-d), and a compound represented by any of the following formulas (2-a) to (2-c).

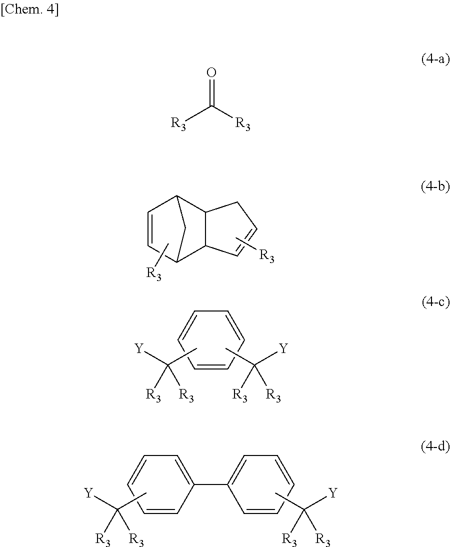

In formulas (4-a) to (4-d), each of the multiple R₃s independently represents a hydrogen atom or a hydrocarbon group having 1 to 10 carbon atoms. Each of the multiple Ys independently represents a hydrogen atom, a fluorine atom, a chlorine atom, a bromine atom, an iodine atom, a hydroxy group, or an alkoxy group having 1 to 6 carbon atoms.

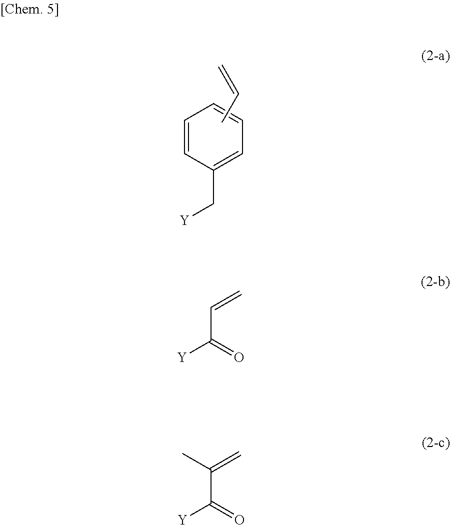

In formulas (2-a) to (2-c), a plurality of Ys each independently represent a hydrogen atom, a fluorine atom, a chlorine atom, a bromine atom, an iodine atom, a hydroxy group, or an alkoxy group having 1 to 6 carbon atoms.

[3] A curable resin obtained by reacting a phenolic resin obtained by reacting a polyhydroxy resin represented by the following formula (3) with a C9 petroleum resin (P1) having a double bond, and a compound represented by any one of the following formulas (2-a) to (2-c).

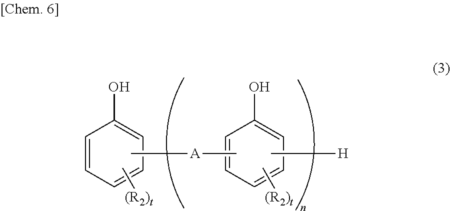

In formula (3), A represents any one of the following formulas (1-a) to (1-d). Each of the multiple R₂ independently represents a hydrogen atom, a hydrocarbon group having 1 to 10 carbon atoms, an alkoxy group having 1 to 6 carbon atoms, an amino group, or a hydroxy group. Each of the multiple t independently represents an integer of 0 to 3. The average value tₐᵥₑ of t is 0≤tₐᵥₑ≤2. n is the number of repetitions, and the average value nₐᵥₑ of n is 0.1≤nₐᵥₑ≤5.

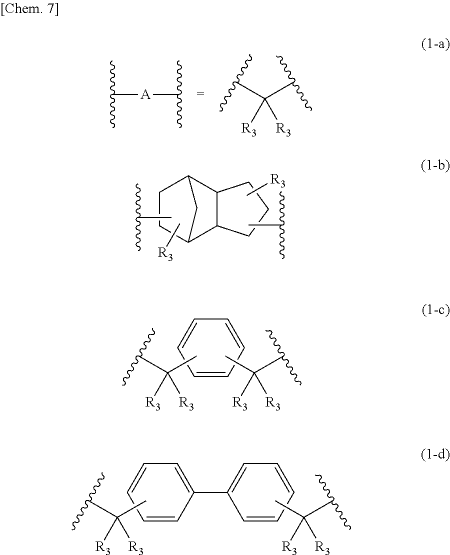

In formulas (1-a) to (1-d), each of the multiple R₃s independently represents a hydrogen atom or a hydrocarbon group having 1 to 10 carbon atoms. The wavy line represents a bonding site to the aromatic ring in formula (3).

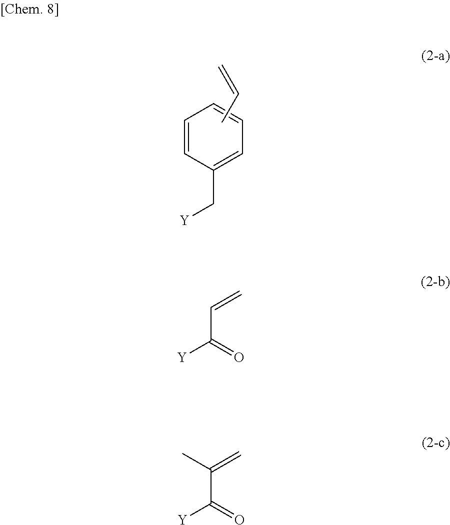

In formulas (2-a) to (2-c), a plurality of Ys each independently represent a hydrogen atom, a fluorine atom, a chlorine atom, a bromine atom, an iodine atom, a hydroxy group, or an alkoxy group having 1 to 6 carbon atoms.

[4] A curable resin composition comprising the curable resin according to any one of [1] to [3].

[5] The curable resin composition according to [4], further comprising a polyphenylene ether resin.

[6] The curable resin composition according to [4] or [5], further comprising a maleimide resin.

[7] The curable resin composition according to any one of [4] to [6], further comprising a polyolefin resin or a polystyrene resin.

[8] The curable resin composition according to any one of [4] to [7], further comprising an inorganic filler.

[9] The curable resin composition according to any one of [4] to [8], further comprising a curing accelerator.

[10] The curable resin composition according to any one of [4] to [9], further comprising a polymerization initiator.

[11] A cured product of the curable resin composition according to any one of [4] to [10] above.

[12] A prepreg obtained by using the curable resin composition according to any one of [4] to [10].

[13] A laminate obtained by curing the curable resin composition according to any one of the items [4] to [10].

[14] A semiconductor substrate comprising the laminate according to the item [13].

### Advantageous Effects of Invention

According to the present invention, it is possible to provide a curable resin, a curable resin composition, and a cured product thereof, an insulating layer, a printed wiring board, and a semiconductor device, all of which have excellent dielectric properties.

### BRIEF DESCRIPTION OF DRAWINGS

FIG. 1 shows a GPC chart of Synthesis Example 1.

FIG. 2 shows a ¹H-NMR chart of Synthesis Example 1.

FIG. 3 shows a GPC chart of Example 1.

FIG. 4 shows a ¹H-NMR chart of Example 1.

FIG. 5 shows a GPC chart of Example 2.

FIG. 6 shows a ¹H-NMR chart of Example 2.

FIG. 7 shows an IR chart of Example 2.

### DETAILED DESCRIPTION OF THE PREFERRED EMBODIMENTS

The curable resin of the present embodiment is represented by the following formula (1).

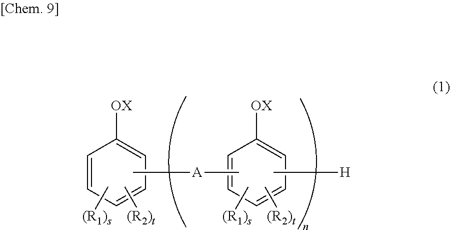

In formula (1), A represents any one of the following formulas (1-a) to (1-d). Each of the multiple X independently represents any one of the following formulas (1-e) to (1-g). Each of the multiple R₁ independently represents a residue obtained by removing one hydrogen atom from a C9 petroleum resin. Each of the multiple R₂ independently represents a hydrogen atom, a hydrocarbon group having 1 to 10 carbon atoms, an alkoxy group having 1 to 6 carbon atoms, an amino group, or a hydroxy group. Each of the multiple s and t independently represents an integer of 0 to 3, and the sum of s and t is an integer of 0 to 3, in which s is the number of R₁ bonded to the same aromatic ring, and t is the number of R₂ bonded to the same aromatic ring. The average value sₐᵥₑ of s is 0<sₐᵥₑ≤3, and the average value tₐᵥₑ of t is 0≤tₐᵥₑ≤2. n is the number of repetitions, and the average value nₐᵥₑ of n is 0.1≤nₐᵥₑ≤5.

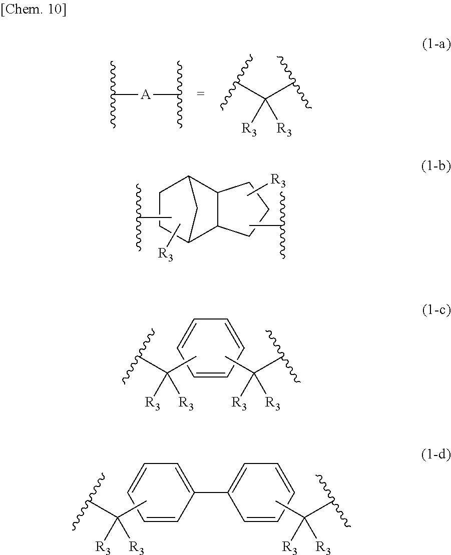

In formulas (1-a) to (1-d), each of the multiple R₃ independently represents a hydrogen atom or a hydrocarbon group having 1 to 10 carbon atoms. The wavy line represents a bonding site to the aromatic ring in formula (1).

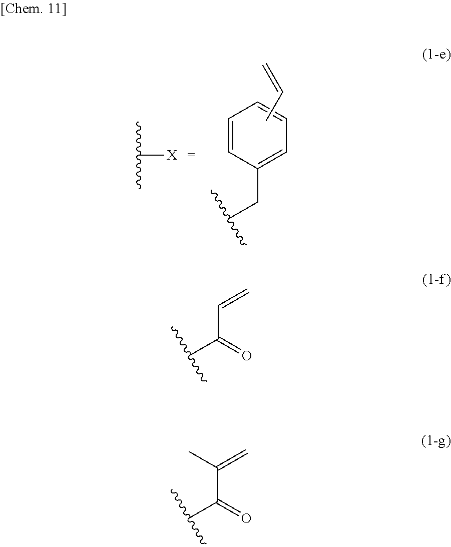

In formulas (1-e) to (1-g), the wavy lines represent the bonding sites to the oxygen atom in formula (1).

The C9 petroleum resin refers to a resin (C9 petroleum resin) obtained by polymerizing a C9 fraction (styrene, vinyltoluene, indene, a-methylstyrene, dicyclopentadiene, etc.) obtained by thermal decomposition of petroleum naphtha.

Industrially available C9 petroleum resins include, but are not limited to: C9 petroleum resins manufactured by Maruzen Petrochemical Co., Ltd.; T-REZ RD-104, T-REZ PR802, Neopolymer L-90, Neopolymer 120, Neopolymer 130, Neopolymer 140, Neopolymer 150, Neopolymer 160, Neopolymer 170S, Neopolymer M-1, Neopolymer S, Neopolymer S100, Neopolymer 120S, Neopolymer 130S, Neopolymer 120P, Neopolymer E-100, Neopolymer E-130, and Neoresin EP-140 manufactured by ENEOS Corporation; Petrotack 60, Petrotack 70, Petrotack 90, Petrotack 90V, Petrotack 90HS, Petrotack 100V, Petokol LX, Petokol 120, Petokol 130, and Petokol 140 manufactured by Tosoh Corporation; NP-10, NP-25, NEVPENE9545, NEVEX045, NEVCHEM100, NEVCHEM110, NEVCHEM120, NEVCHEM130, NEVCHEM140, NEVCHEM150, NEVCHEM200, NEVCHEM220, NEVCHEM240, NEVCHEM250, NEVCHEM300, NEVCHEM320, NEVCHEM340, NEVPENE9500, NEVPENE9510, NEVPENE9510-N, and NEVPENE9511 manufactured by NEVILLE Chemical Co., Ltd. The water absorption rate of C9 petroleum resins is reduced due to the influence of low polarity alkyl groups in the skeleton, and therefore the dielectric properties can be improved over a long period of time.

The number average molecular weight of the curable resin represented by the above formula (1) of this embodiment can be determined by gel permeation chromatography (GPC, detector: RI), and is preferably 300 to 10,000, more preferably 500 to 5,000, and particularly preferably 750 to 3,000.

The average value nₐᵥₑ of n in the formula (1) can be determined by gel permeation chromatography (GPC, detector: RI) or ¹H-NMR measurement. n is preferably 0≤n≤20, more preferably 0<n<10. The average value nₐᵥₑ of n is 0.1≤nₐᵥₑ≤5, preferably 0.5≤nₐᵥₑ≤5, more preferably 1≤nₐᵥₑ≤3. When nₐᵥₑ is greater than 5, the solubility in a solvent and the flowability are poor, making molding difficult. When nₐᵥₑ is less than 0.1, the crosslink density of the cured product is low, and sufficient heat resistance is not exhibited.

In the formula (1), the average value of s can be calculated from the charge ratio of the polyhydroxy resin represented by the formula (3) described later and the C9 petroleum resin (P1) having a double bond, or the charge ratio of the C9 petroleum resin (P2) having a phenolic hydroxy group in the phenolic resin (P3). s is preferably 0<s≤3. The average value sₐᵥₑ of s is preferably 0<sₐᵥₑ≤3, more preferably 0.1≤sₐᵥₑ≤2, and particularly preferably 0.3≤sₐᵥₑ≤1.5. t is preferably 0≤t≤2. The average value tₐᵥₑ of t is preferably 0≤tₐᵥₑ≤2, more preferably 0≤tₐᵥₑ≤1.5, and particularly preferably 0≤tₐᵥₑ≤1. However, the sum of s and t is an integer of 0 to 3, in which s is the number of R₁ bonded to the same aromatic ring, and t is the number of R₂. When sₐᵥₑ is 0, properties such as dielectric properties remain unimproved, and when it is more than 3, the functional group density becomes too low and curability tends to decrease. Also, when tₐᵥₑ is more than 2, the functional group density becomes low and curability tends to decrease.

The curable resin represented by formula (1) is derived from a phenolic resin represented by formula (2) below. Specifically, the curable resin represented by formula (1) above can be obtained by reacting the phenolic resin represented by formula (2) below with a compound represented by any one of formulas (2-a), (2-b), and (2-c) below.

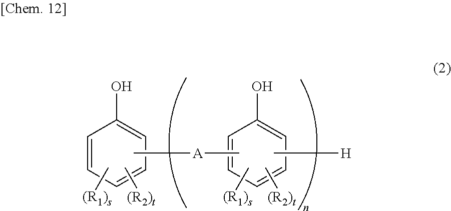

In formula (2), R₁, R₂, n, s and t have the same meanings as in formula (1).

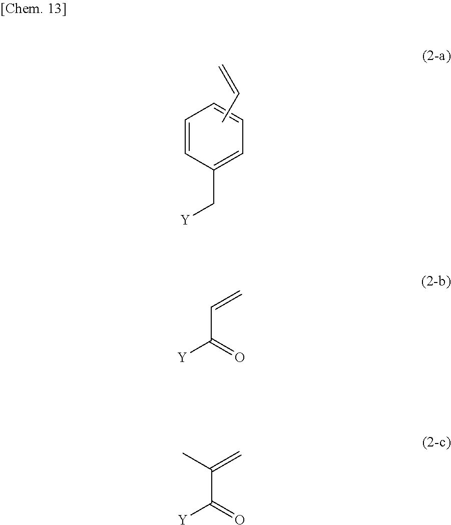

In formulas (2-a) to (2-c), Y represents any one of a hydrogen atom, a fluorine atom, a chlorine atom, a bromine atom, an iodine atom, a hydroxy group, and an alkoxy group having 1 to 6 carbon atoms.

The method for producing the curable resin represented by formula (1) is not particularly limited, but a typical method is to charge a phenolic resin represented by formula (2), any one of the compounds represented by formulas (2-a) to (2-c), a basic catalyst, and a solvent into a reaction vessel all at once and carry out a dehydrohalogenation reaction at a predetermined temperature, or to charge a polyhydroxy resin and a catalyst, and while maintaining the temperature at a predetermined level, carry out the reaction while dropping any one of the compounds represented by formulas (2-a) to (2-c). In this case, the drop time is usually 1 to 10 hours.

Examples of the solvent used in the production of the curable resin represented by the formula (1) include, but are not limited to, non-aqueous solvents such as: aromatic solvents such as toluene and xylene; aliphatic solvents such as cyclohexane and n-hexane; ethers such as diethyl ether, diisopropyl ether, and 4-methyltetrahydropyran; ester solvents such as ethyl acetate and butyl acetate; and ketone solvents such as methyl isobutyl ketone and cyclopentanone. Two or more of these may be used in combination. In addition to the non-aqueous solvent, aprotic polar solvents may also be used in combination. Examples include dimethyl sulfone, dimethyl sulfoxide, dimethylformamide, dimethylacetamide, 1,3-dimethyl-2-imidazolidinone, and N-methylpyrrolidone, and two or more of these may be used in combination. When using an aprotic polar solvent, it is preferable to use one having a higher boiling point than the non-aqueous solvent to be used in combination.

The catalyst used in the production of the curable resin represented by the formula (1) is not particularly limited, and examples thereof include basic catalysts such as sodium hydroxide, potassium hydroxide, and potassium carbonate. Since it is difficult to completely proceed with the dehydrohalogenation reaction, the aprotic polar solvent may be used in large excess relative to the substrate, and the dehydrohalogenation reaction may be repeated two or more times. For example, the dehydrohalogenation reaction of the curable resin represented by the formula (1) may be carried out in an organic solvent in the presence of a base catalyst, and the resulting solution may be washed with water and then returned to the reaction vessel, and the base catalyst may be added to cause the reaction again. In this way, the progress of the dehydrohalogenation reaction can be increased. That is, it is possible to reduce the amount of residual halogen contained in the target compound. If a solvent is used after the reaction, the catalyst component may be removed as necessary, and the solvent may then be distilled off to obtain the resin used in this embodiment.

The curable resin represented by the formula (1) can be purified by a known method. The purification method is not particularly limited, but includes separation and washing with water, reprecipitation using a poor solvent, etc. By adding a purification step, it is possible to remove phenolic hydroxy groups derived from the raw materials and alcoholic hydroxy groups produced during the reaction, and the like, and it is possible to improve the dielectric properties.

Next, a method for producing the phenolic resin represented by the formula (2) will be described. The method for producing the phenolic resin represented by the formula (2) is not particularly limited, but an example of the method is a method obtained by subjecting a polyhydroxy resin represented by the following formula (3) to an addition reaction with a C9 petroleum resin (P1) having a double bond. Another method is a method obtained by reacting a phenolic resin (P3) containing a C9 petroleum resin (P2) having a phenolic hydroxy group with any of the compounds represented by the following formulas (4-a) to (4-d).

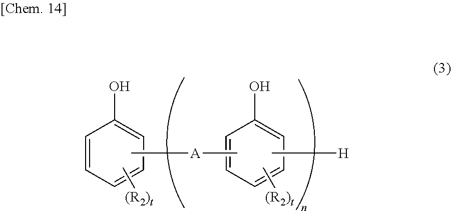

In formula (3), A, R₂, n and t have the same meanings as in formula (1).

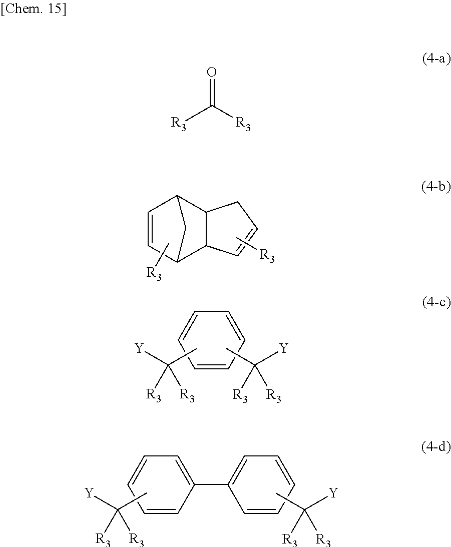

In the formulas (4-a) to (4-d), R₃ has the same meaning as in the formulas (1-a) to (1-d), and Y has the same meaning as in the formula (2-a).

The polyhydroxy resin represented by the formula (3) is a compound having a phenolic hydroxy group in the molecule. Examples of the phenolic resin include, but are not limited to, the reaction product of phenols and aldehydes, the reaction product of phenols and diene compounds, the reaction product of phenols and ketones, the reaction product of phenols and substituted biphenyls, the reaction product of phenols and substituted phenyls, and the reaction product of bisphenols and aldehydes. These may be used alone or in combination.

### [C9 Petroleum Resin (P1) Having a Double Bond]

The C9 petroleum resin (P1) having a double bond can be obtained by cationic polymerization of at least one of the compounds represented by the following formulas (5-a) to (5-c) in the presence of an acid catalyst.

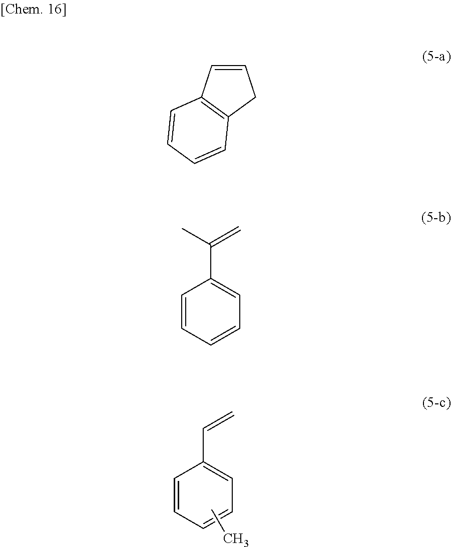

The C9 petroleum resin (P1) having a double bond preferably has a number average molecular weight of 200 to 10,000, more preferably 300 to 5,000, and even more preferably 500 to 3,000.

### [C9 Petroleum Resin (P2) Having a Phenolic Hydroxy Group]

The C9 petroleum resin (P2) having a phenolic hydroxy group is not particularly limited, but can be obtained by reacting a C9 petroleum resin (P1) having a double bond with a polyhydroxy compound. Specific examples of the C9 petroleum resin (P2) having a phenolic hydroxy group include Neopolymer E-100 and Neopolymer E-130 manufactured by ENEOS Corporation. The C9 petroleum resin (P2) having a phenolic hydroxy group usually has a number average molecular weight of 200 to 5,000, preferably 300 to 3,000, and more preferably 500 to 1,000.

### [Phenolic Resin (P3) Containing C9 Petroleum Resin (P2) Having Phenolic Hydroxy Groups]

The phenolic resin (P3) containing C9 petroleum resin (P2) having phenolic hydroxy groups contains C9 petroleum resin (P2) having phenolic hydroxy groups as an essential component, and may further contain other phenols. Other phenols that can be combined are not particularly limited as long as they are compounds having a phenolic hydroxy group, and examples thereof include: monofunctional phenol compounds such as phenol, alkyl-substituted phenols, aromatic-substituted phenols, naphthol, alkyl-substituted naphthol, dihydroxybenzene, alkyl-substituted dihydroxybenzene, and dihydroxynaphthalene; bisphenols such as bisphenol A, bisphenol F, bisphenol S, biphenol, bisphenol AD, bisphenol I, etc.; and polycondensates of these phenol compounds with various aldehydes such as formaldehyde, acetaldehyde, alkyl aldehyde, benzaldehyde, alkyl-substituted benzaldehyde, hydroxybenzaldehyde, naphthaldehyde, glutaraldehyde, phthalaldehyde, crotonaldehyde, cinnamaldehyde.

In the production of the phenolic resin represented by the formula (2), a solvent can be used in the presence of an acidic or basic catalyst as necessary. Examples of the solvent to be used include, but are not limited to: non-aqueous solvents such as aromatic solvents such as toluene and xylene; aliphatic solvents such as cyclohexane and n-hexane; ethers such as diethyl ether, diisopropyl ether, and 4-methyltetrahydropyran; ester solvents such as ethyl acetate and butyl acetate; and ketone solvents such as methyl isobutyl ketone and cyclopentanone. Two or more of these may be used in combination. In addition to the non-aqueous solvent, an aprotic polar solvent can also be used in combination. Examples include dimethyl sulfone, dimethyl sulfoxide, dimethylformamide, dimethylacetamide, 1,3-dimethyl-2-imidazolidinone, and N-methylpyrrolidone, and two or more of these may be used in combination. When an aprotic polar solvent is used, it is preferable to use one having a higher boiling point than the non-aqueous solvent to be used in combination.

The catalyst used in the production of the phenolic resin represented by the formula (2) is not particularly limited, and examples thereof include: known acid catalysts such as: mineral acids such as hydrochloric acid, sulfuric acid, phosphoric acid; organic acids such as oxalic acid, methanesulfonic acid, toluenesulfonic acid, acetic acid; heteropolyacids such as tungstic acid; activated clay, inorganic acids, stannic chloride, zinc chloride, ferric chloride, and the like, and other organic and inorganic acid salts exhibiting acidity; or alkali metal hydroxides such as lithium hydroxide, sodium hydroxide, and potassium hydroxide; alkaline earth metal hydroxides such as magnesium hydroxide and calcium hydroxide; alkali metal alkoxides such as sodium methoxide, sodium ethoxide, potassium methoxide, potassium ethoxide, and potassium-tert-butoxide; and alkaline earth metal alkoxides such as magnesium methoxide and magnesium ethoxide. Amine-based catalysts may also be used, and examples thereof include triethylamine, ethanolamine, pyridine, piperidine, and morpholine. In particular, when an amine-based catalyst is used, it can also be used as a solvent. These catalysts may be used alone or in combination of two or more. The amount of the catalyst used is usually 0.001 to 10 times by mole, preferably 0.01 to 2 times by mole, relative to the polyhydroxy resin represented by the formula (3) or the polymer (P2) containing a C9 petroleum resin structure having a phenolic hydroxy group. When the catalyst is used as a solvent, it is preferable to add about 10 to 200% by mass relative to the polyhydroxy hydroxy resin represented by the formula (3) or the polymer (P2) containing a C9 petroleum resin structure having a phenolic hydroxy group.

The curable resin of the present embodiment can also be used as a curable resin composition. The composition is not limited, but examples include epoxy resins, active ester compounds, maleimide compounds, phenolic resins, polyphenylene ether compounds, amine resins, compounds containing ethylenically unsaturated bonds, isocyanate resins, polyamide resins, polyimide resins, cyanate ester resins, polybutadiene and modified products thereof, polystyrene and modified products thereof, inorganic fillers, curing accelerators, polymerization initiators, polymerization inhibitors, flame retardants, light stabilizers, binder resins, and additives. These may be used alone or in combination. Of these compounds, it is preferable to contain polyphenylene ether compounds, maleimide compounds, compounds having ethylenically unsaturated bonds, cyanate ester resins, polybutadiene and modified products thereof, and polystyrene and modified products thereof, in view of the balance of heat resistance, adhesion, and dielectric properties. By containing these compounds, the brittleness of the cured product can be improved and adhesion to metals can be improved, and cracks in the package during solder reflow and reliability tests such as thermal cycles can be suppressed. The amounts of the compounds used are preferably 10 times by mass or less, more preferably 5 times by mass or less, and particularly preferably 3 times by mass or less, relative to the curable resin composition, unless otherwise specified. The preferred lower limit is 0.1 times by mass or more, more preferably 0.25 times by mass or more, and even more preferably 0.5 times by mass or more. Within the above range, the effect of each compound added can be added while taking advantage of the effect of the dielectric properties of the curable resin composition of this embodiment. As for these components, the following exemplified ones can be used.

### [Epoxy Resin]

The curable resin composition of the present embodiment may contain an epoxy resin. Examples of the epoxy resin to be contained are shown below, but are not limited thereto. These may be used alone or in combination.

Of the above-mentioned epoxy resins, examples of liquid epoxy resins include bisphenol A type epoxy resins, bisphenol F type epoxy resins, bisphenol AF type epoxy resins, naphthalene type epoxy resins, glycidyl ester type epoxy resins, glycidyl amine type epoxy resins, phenol novolac type epoxy resins, alicyclic epoxy resins having an ester skeleton, cyclohexane type epoxy resins, cyclohexane dimethanol type epoxy resins, glycidyl amine type epoxy resins, and epoxy resins having a butadiene structure. Of these, bisphenol A type epoxy resins are particularly preferred. Specific examples include “RE310S”, “RE410S” (all manufactured by Nippon Kayaku Co., Ltd., bisphenol A type epoxy resin), “RE303S”, “RE304S”, “RE403S”, “RE404S” (all manufactured by Nippon Kayaku Co., Ltd., bisphenol F type epoxy resin), “HP4032”, “HP4032D”, “HP4032SS” (all manufactured by DIC Corporation, naphthalene type epoxy resin), “828US”, “jER828EL”, “825”, “828EL” (all manufactured by Mitsubishi Chemical Corporation, bisphenol A type epoxy resin), “jE807”, “1750” (all manufactured by Mitsubishi Chemical Corporation, bisphenol F type epoxy resin), “jER152” (manufactured by Mitsubishi Chemical Corporation, phenol novolac type epoxy resin), “630”, “630LSD” (all manufactured by Mitsubishi Chemical Corporation, glycidylamine type epoxy resin), “ZX1059” (manufactured by Nippon Steel Chemical & Material Co., Ltd., mixture of bisphenol A type epoxy resin and bisphenol F type epoxy resin), “EX-721” (manufactured by Nagase ChemteX Corporation, glycidyl ester type epoxy resin), “Celloxide 2021P” (manufactured by Daicel Corporation, alicyclic epoxy resin having an ester skeleton), “PB-3600” (manufactured by Daicel Corporation, epoxy resin having a butadiene structure), “ZX1658”, “ZX1658GS” (all manufactured by Nippon Steel Chemical & Material Co., Ltd., liquid 1,4-glycidylcyclohexane type epoxy resin). These may be used alone or in combination of two or more.

Of the above-mentioned epoxy resins, preferred examples of solid epoxy resins include bixylenol-type epoxy resins, naphthalene-type epoxy resins, naphthalene-type tetrafunctional epoxy resins, cresol novolac-type epoxy resins, dicyclopentadiene-type epoxy resins, trisphenol-type epoxy resins, naphthol-type epoxy resins, biphenyl-type epoxy resins, naphthylene ether-type epoxy resins, anthracene-type epoxy resins, bisphenol A-type epoxy resins, bisphenol AF-type epoxy resins, and tetraphenylethane-type epoxy resins, and examples of such solid epoxy resins include naphthol-type epoxy resins, bisphenol AF-type epoxy resins, naphthalene-type epoxy resins, and biphenyl-type epoxy resins. Specific examples include “HP4032H” (manufactured by DIC Corporation, naphthalene type epoxy resin), “HP-4700”, and “HP-4710” (manufactured by DIC Corporation, naphthalene type tetrafunctional epoxy resin), “N-690” (manufactured by DIC Corporation, cresol novolac type epoxy resin), “N-695” (manufactured by DIC Corporation, cresol novolac type epoxy resin), “HP-7200”, “HP-7200HH”, and “HP-7200H” (all manufactured by DIC Corporation, dicyclopentadiene type epoxy resin), “EXA-7311”, “EXA-7311-G3”, “EXA-7311-G4”, “EXA-7311-G4S”, “HP-6000” (all manufactured by DIC Corporation, naphthylene ether type epoxy resin), “EPPN-502H” (manufactured by Nippon Kayaku Co., Ltd., trisphenol type epoxy resin), “NC-7000L”, “NC-7300” (all manufactured by Nippon Kayaku Co., Ltd., naphthol-cresol novolac type epoxy resin), “NC-3000H”, “NC-3000”, “NC-3000L”, “NC-3100” (all manufactured by Nippon Kayaku Co., Ltd., biphenyl aralkyl type epoxy resin), “XD-1000-2L”, “XD-1000-L”, “XD-1000-H”, (all manufactured by Nippon Kayaku Co., Ltd., dicyclopentadiene type epoxy resin), “ESN475V” (manufactured by Nippon Steel Chemical & Material Co., Ltd., naphthol type epoxy resin), “ESN485” (manufactured by Nippon Steel Chemical & Material Co., Ltd., naphthol novolac type epoxy resin), “YX-4000H”, “YX-4000”, “YL6121” (all manufactured by Mitsubishi Chemical Corporation, biphenyl type epoxy resin), “YX-4000HK” (manufactured by Mitsubishi Chemical Corporation, bixylenol type epoxy resin), “YX-8800” (manufactured by Mitsubishi Chemical Corporation, anthracene type epoxy resin), “PG-100”, “CG-500” (manufactured by Osaka Gas Chemicals Co., Ltd., fluorene type epoxy resin), “YL-7760” (manufactured by Mitsubishi Chemical Corporation, bisphenol AF type epoxy resin), “YL-7800” (manufactured by Mitsubishi Chemical Corporation, fluorene type epoxy resin), “jER1010” (manufactured by Mitsubishi Chemical Corporation, solid bisphenol A type epoxy resin), “jER1031S” (manufactured by Mitsubishi Chemical Corporation, tetraphenylethane type epoxy resin), etc. These may be used alone or in combination of two or more.

### [Active Ester Compound]

The curable resin composition of the present embodiment may contain an active ester compound. The active ester compound refers to a compound that contains at least one ester bond in the structure and has an aliphatic chain, an aliphatic ring, or an aromatic ring bonded to both sides of the ester bond. For example, compounds having two or more highly reactive ester groups in one molecule, such as phenol esters, thiophenol esters, N-hydroxyamine esters, and esters of heterocyclic hydroxy compounds, can be mentioned, and are obtained by a condensation reaction between at least one compound of a carboxylic acid compound, an acid chloride, or a thiocarboxylic acid compound and at least one compound of a hydroxy compound or a thiol compound. In particular, from the viewpoint of improving heat resistance, it is preferable to obtain it from a carboxylic acid compound or an acid chloride and a hydroxy compound, and the hydroxy compound is preferably a phenol compound or a naphthol compound.

In addition, it is preferable that the active ester compound has a vinyl group. Examples of the active ester compound having a vinyl group include the compounds described in Example 2 of WO 2020/095829 and the compounds disclosed in WO 2020/059625. These may be used alone or in combination of two or more.

Examples of the carboxylic acid compound include benzoic acid, acetic acid, succinic acid, maleic acid, itaconic acid, phthalic acid, isophthalic acid, terephthalic acid, and pyromellitic acid.

Examples of the acid chloride include acetyl chloride, acrylic acid chloride, methacrylic acid chloride, malonyl chloride, succinic acid dichloride, diglycolyl chloride, glutaric acid dichloride, suberic acid dichloride, sebacic acid dichloride, adipic acid dichloride, dodecandioyl dichloride, azelaoyl chloride, 2,5-furandicarbonyl dichloride, phthaloyl chloride, isophthaloyl chloride, terephthaloyl chloride, trimesic acid chloride, bis(4-chlorocarbonylphenyl) ether, 4,4′-diphenyldicarbonyl chloride, and 4,4′-azodibenzoyl dichloride.

Examples of the phenol compound and naphthol compound include hydroquinone, resorcin, bisphenol A, bisphenol F, bisphenol S, phenolphthaline, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, dicyclopentadiene-type diphenol compound, phenol novolak, and phenolic resins described below. Here, the term “dicyclopentadiene-type diphenol compound” refers to a diphenol compound obtained by condensing one molecule of dicyclopentadiene with two molecules of phenol.

Preferred specific examples of the active ester compound include an active ester compound containing a dicyclopentadiene-type diphenol structure, an active ester compound containing a naphthalene structure, an active ester compound containing an acetylated product of phenol novolac, and an active ester compound containing a benzoylated product of phenol novolac. Among these, an active ester compound containing a naphthalene structure and an active ester compound containing a dicyclopentadiene-type diphenol structure are more preferred. The dicyclopentadiene-type diphenol structure refers to a divalent structural unit consisting of phenylene-dicyclopentylene-phenylene.

Commercially available active ester compounds include, for example: active ester compounds containing a dicyclopentadiene-type diphenol structure such as “EXB9451”, “EXB9460”, “EXB9460S”, “HPC-8000-65T”, “HPC-8000H-65TM”, “EXB-8000L-65TM”, and “EXB-8150-65T” (manufactured by DIC Corporation); active ester compounds containing a naphthalene structure such as “EXB9416-70BK” (manufactured by DIC Corporation); and active ester compounds containing an acetylated phenol novolac such as “DC808” (manufactured by Mitsubishi Chemical Corporation); active ester compounds containing a benzoylated phenol novolac such as “YLH1026”, “YLH1030”, and “YLH1048” (manufactured by Mitsubishi Chemical Corporation); an active ester curing agent which is an acetylated phenol novolac such as “DC808” (manufactured by Mitsubishi Chemical Corporation); and an active ester curing agent containing a phosphorus atom such as “EXB-9050L-62M” (manufactured by DIC Corporation).

### [Maleimide Compound]

The curable resin composition of the present embodiment may contain a maleimide compound. A maleimide compound is a compound having one or more maleimide groups in the molecule. Examples of the maleimide compound include 4,4′-diphenylmethane bismaleimide, polyphenylmethane maleimide, m-phenylene bismaleimide, 2,2′-bis[4-(4-maleimidophenoxy)phenyl]propane, 3,3′-dimethyl-5,5′-diethyl-4,4′-diphenylmethane bismaleimide, 4-methyl-1,3-phenylene bismaleimide, 4,4′-diphenylether bismaleimide, 4,4′-diphenylsulfone bismaleimide, 1,3-bis(3-maleimidophenoxy)benzene, 1,3-bis(4-maleimidophenoxy)benzene), Zylok type maleimide compound (anilix maleimide, manufactured by Mitsui Fine Chemicals Co., Ltd.), biphenylaralkyl type maleimide compound (solids obtained by distilling off the solvent under reduced pressure from a resin solution containing the maleimide compound (M2) described in Example 4 of JP2009-001783A), bisaminocumylbenzene type maleimide (maleimide compound described in WO2020/054601A), maleimide compounds having an indane structure described in JP6629692B or WO2020/217679, maleimide compounds described in MATERIAL STAGE, Vol. 18, No. 12, 2019 “Sequel Epoxy Resin CAS Number Story—Hardener CAS Number Memorandum No. 31 Bismaleimide (1)” and MATERIAL STAGE Vol. 19, No. 2, 2019 “Sequel Epoxy Resin CAS Number Story—Hardener CAS Number Memorandum, No. 32 Bismaleimide (2)” and the like, but are not limited thereto. In addition, these may be used alone or in combination.

The amount of the maleimide compound added is preferably 10 times by mass or less, more preferably 5 times by mass or less, and particularly preferably 3 times by mass or less, relative to the curable resin of this embodiment. The lower limit is preferably 0.01 times by mass or more, and more preferably 0.1 times by mass or more. Within the above range, the dielectric properties and low water absorption effects of the curable resin of this embodiment can be utilized.

### [Phenolic Resin]

A phenolic resin is a compound having two or more phenolic hydroxy groups in a molecule. Examples of the phenolic resin include, but are not limited to, a reaction product of a phenol with an aldehyde, a reaction product of a phenol with a diene compound, a reaction product of a phenol with a ketone, a reaction product of a phenol with a substituted biphenyl, a reaction product of a phenol with a substituted phenyl, a reaction product of a bisphenol with an aldehyde, and the like. These may be used alone or in combination.

Specific examples of the above-mentioned raw materials are given below, but the raw materials are not limited thereto.
<Phenols> Phenol, alkyl-substituted phenols, aromatic substituted phenols, hydroquinone, resorcin, naphthol, alkyl-substituted naphthol, dihydroxybenzene, alkyl-substituted dihydroxybenzene, dihydroxynaphthalene, etc.
<Aldehydes> formaldehyde, acetaldehyde, alkyl aldehyde, benzaldehyde, alkyl-substituted benzaldehyde, hydroxybenzaldehyde, naphthaldehyde, glutaraldehyde, phthalaldehyde, crotonaldehyde, cinnamaldehyde, furfural, etc.
<Diene compounds> dicyclopentadiene, terpenes, vinylcyclohexene, norbomadiene, vinylnorbornene, tetrahydroindene, divinylbenzene, divinylbiphenyl, diisopropenylbiphenyl, butadiene, isoprene, and the like.
<Ketones> Acetone, methyl ethyl ketone, methyl isobutyl ketone, acetophenone, benzophenone, fluorenone, etc.
<Substituted Biphenyls> 4,4′-bis(chloromethyl)-1,1′-biphenyl, 4,4′-bis(methoxymethyl)-1,1′-biphenyl, 4,4′-bis(hydroxymethyl)-1,1′-biphenyl, and the like.
<Substituted phenyls> 1,4-bis(chloromethyl)benzene, 1,4-bis(methoxymethyl)benzene, 1,4-bis(hydroxymethyl)benzene, and the like.

### [Polyphenylene Ether Compound]

From the viewpoints of heat resistance and electrical properties, the polyphenylene ether compound is preferably a polyphenylene ether compound having an ethylenically unsaturated bond, and more preferably a polyphenylene ether compound having an acrylic group, a methacrylic group, or a styrene structure. Commercially available products include SA-9000 (manufactured by SABIC, a polyphenylene ether compound having a methacrylic group) and OPE-2St 1200 (manufactured by Mitsubishi Gas Chemical Company, a polyphenylene ether compound having a styrene structure).

The number average molecular weight (Mn) of the polyphenylene ether compound is preferably 500 to 5000, more preferably 2000 to 5000, and more preferably 2000 to 4000. If the molecular weight is less than 500, the heat resistance of the cured product tends to be insufficient. If the molecular weight is more than 5000, the melt viscosity increases and sufficient fluidity cannot be obtained, which tends to lead to molding defects. In addition, the reactivity decreases, the curing reaction takes a long time, and the amount of unreacted material that is not incorporated into the curing system increases, which decreases the glass transition temperature of the cured product and tends to decrease the heat resistance of the cured product.

If the number average molecular weight of the polyphenylene ether compound is 500 to 5000, it is possible to exhibit excellent heat resistance, moldability, etc. while maintaining excellent dielectric properties. The number average molecular weight here can be specifically measured using gel permeation chromatography, etc.

The polyphenylene ether compound may be one obtained by a polymerization reaction, or one obtained by a redistribution reaction of a high molecular weight polyphenylene ether compound having a number average molecular weight of about 10,000 to 30,000. In addition, these may be used as raw materials and reacted with a compound having an ethylenically unsaturated bond, such as methacryl chloride, acrylic chloride, or chloromethylstyrene, to impart radical polymerizability. The polyphenylene ether compound obtained by the redistribution reaction is obtained, for example, by heating a high molecular weight polyphenylene ether compound in a solvent such as toluene in the presence of a phenolic compound and a radical initiator to cause a redistribution reaction. The polyphenylene ether compound obtained by the redistribution reaction in this way has hydroxy groups derived from a phenolic compound that contributes to curing at both ends of the molecular chain, and is therefore preferable in that it can maintain even higher heat resistance, and that functional groups can be introduced at both ends of the molecular chain even after modification with a compound having an ethylenically unsaturated bond. In addition, the polyphenylene ether compound obtained by the polymerization reaction is preferable in that it exhibits excellent fluidity.

The molecular weight of the polyphenylene ether compound can be adjusted by adjusting the polymerization conditions, etc., in the case of a polyphenylene ether compound obtained by a polymerization reaction. In addition, in the case of a polyphenylene ether compound obtained by a redistribution reaction, the molecular weight of the obtained polyphenylene ether compound can be adjusted by adjusting the conditions, etc., of the redistribution reaction. More specifically, it is possible to adjust the amount of the phenolic compound used in the redistribution reaction. That is, the greater the amount of the phenolic compound, the lower the molecular weight of the obtained polyphenylene ether compound. In this case, poly(2,6-dimethyl-1,4-phenylene ether) or the like can be used as the high molecular weight polyphenylene ether compound that undergoes the redistribution reaction. In addition, the phenolic compound used in the redistribution reaction is not particularly limited, but for example, a polyfunctional phenolic compound having two or more phenolic hydroxy groups in the molecule, such as bisphenol A, phenol novolac, cresol novolac, etc., is preferably used. These may be used alone or in combination of two or more.

The content of the polyphenylene ether compound is not particularly limited, but is preferably 5 to 1000 parts by mass, and more preferably 10 to 750 parts by mass, when the total mass of the curable resin composition is 100 parts by mass. When the content of the polyphenylene ether compound is in the above range, it is preferable in that a cured product is obtained that is not only excellent in heat resistance, etc., but also fully exhibits the excellent dielectric properties of the polyphenylene ether compound.

### [Amine Resin]

The amine resin is a compound having two or more amino groups in the molecule. Examples of the amine resin include, but are not limited to: diaminodiphenylmethane, diaminodiphenylsulfone, isophoronediamine, naphthalenediamine, aniline novolak (a reaction product of aniline and formalin), N-methylaniline novolak (a reaction product of N-methylaniline and formalin), orthoethylaniline novolak (a reaction product of orthoethylaniline and formalin), a reaction product of 2-methylaniline and formalin, a reaction product of 2,6-diisopropylaniline and formalin, a reaction product of 2,6-diethylaniline and formalin, a reaction product of 2-ethyl-6-ethylaniline and formalin, a reaction product of 2,6-dimethylaniline and formalin, and a reaction product obtained by reacting aniline and xylylene chloride, a reaction product of aniline and substituted biphenyls (such as 4,4′-bis(chloromethyl)-1,1′-biphenyl and 4,4′-bis(methoxymethyl)-1,1′-biphenyl) disclosed in Japanese Patent No. 6429862, a reaction product of aniline and a substituted phenyls (such as 1,4-bis(chloromethyl)benzene, 1,4-bis(methoxymethyl)benzene, and 1,4-bis(hydroxymethyl)benzene), 4,4′-(1,3-phenylenediisopropylidene)bisaniline, 4,4′-(1,4-phenylenediisopropylidene)bisaniline, a reaction product of aniline and diisopropenylbenzene, dimer diamine, etc. Furthermore, these may be used alone or in combination.

### [Compound Containing an Ethylenically Unsaturated Bond]

The compound containing an ethylenically unsaturated bond is a compound having one or more ethylenically unsaturated bonds in the molecule that can be polymerized by heat or light, regardless of whether a polymerization initiator is used or not. Examples of the compound containing an ethylenically unsaturated bond include, but are not limited to, a reaction product of the phenolic resin with an ethylenically unsaturated bond-containing halogen-based compound (such as chloromethylstyrene, allyl chloride, methallyl chloride, acrylic acid chloride, methacrylic acid chloride), a reaction product of an ethylenically unsaturated bond-containing phenol (such as 2-allylphenol, 2-propenylphenol, 4-allylphenol, 4-propenylphenol, eugenol, isoeugenol) with a halogen-based compound (such as 1,4-bis(chloromethyl)benzene, 4,4′-bis(chloromethyl)biphenyl, 4,4′-difluorobenzophenone, 4,4′-dichlorobenzophenone, 4,4′-dibromobenzophenone, cyanuric chloride), a reaction product of an epoxy resin or alcohol with a (meth)acrylic acid (such as acrylic acid, methacrylic acid), and an acid-modified product thereof. In addition, these may be used alone or in combination.

### [Isocyanate Resin]

An isocyanate resin is a compound having two or more isocyanate groups in the molecule. Examples of the isocyanate resin include: aromatic diisocyanates such as p-phenylene diisocyanate, m-phenylene diisocyanate, p-xylylene diisocyanate, m-xylylene diisocyanate, 2,4-tolylene diisocyanate, 2,6-tolylene diisocyanate, 4,4′-diphenylmethane diisocyanate, and naphthalene diisocyanate; aliphatic or alicyclic diisocyanates such as isophorone diisocyanate, hexamethylene diisocyanate, 4,4′-dicyclohexylmethane diisocyanate, hydrogenated xylene diisocyanate, norbornene diisocyanate, and lysine diisocyanate; polyisocyanates such as one or more biuret forms of isocyanate monomers or isocyanate forms obtained by trimerizing the diisocyanate compounds; and polyisocyanates obtained by a urethanization reaction between the isocyanate compounds and polyol compounds, but are not limited thereto. These may be used alone or in combination.

### [Polyamide Resin]

Examples of polyamide resins include reaction products of one or more of diamines, diisocyanates, and oxazolines with dicarboxylic acids, reaction products of diamines with acid chlorides, and ring-opening polymers of lactam compounds. These may be used alone or in combination.

Specific examples of the above-mentioned raw materials are given below, but the raw materials are not limited thereto.
<Diamines> Ethylenediamine, trimethylenediamine, tetramethylenediamine, pentamethylenediamine, hexamethylenediamine, heptamethylenediamine, octamethylenediamine, nonamethylenediamine, decanediamine, undecanediamine, dodecanediamine, tridecanediamine, tetradecanediamine, pentadecanediamine, hexadecanediamine, heptadecanediamine, octadecanediamine, nonadecanediamine, eicosanediamine, 2-methyl-1,5-diaminopentane, 2-methyl-1,8-diaminooctane, dimer diamine, cyclohexane diamine, bis-(4-aminocyclohexyl)methane, bis(3-methyl-4-aminocyclohexyl)methane, xylylene diamine, norbornane diamine, isophorone diamine, bisaminomethyltricyclodecane, phenylenediamine, diethyltoluenediamine, naphthalenediamine, diaminodiphenylmethane, bis(4-amino-3,5-dimethylphenyl)methane, bis(4-amino-3,5-diethylphenyl) methane, 4,4′-methylenebis-o-toluidine, 4,4′-methylenebis-o-ethylaniline, 4,4′-methylenebis-2-ethyl-6-methylaniline, 4,4′-methylenebis-2,6-diisopropylaniline, 4,4-ethylenedianiline, diaminodiphenyl sulfone, diaminodiphenyl ether, 1,3-bis(3-aminophenoxy)benzene, 1,3-bis(4-aminophenoxy)benzene, 4,4-bis(4-aminophenoxy)biphenyl, 2,2-bis[4-(4-aminophenoxy)phenyl]propane, bis[4-(4-aminophenoxy)phenyl]sulfone, 2,2-bis(3-amino-4-hydroxyphenyl)propane, 2,2-bis(4-aminophenyl)hexafluoropropane, 4,4′-(1,3-phenylenediisopropylidene)bisaniline, 4,4′-(1,4-phenylenediisopropylidene)bisaniline, 9,9-bis(4-aminophenyl)fluorene, 2,7-diaminofluorene, aminobenzylamine, diaminobenzophenone, and the like.
<Diisocyanates> benzene diisocyanate, toluene diisocyanate, 1,3-bis(isocyanatomethyl)benzene, 1,3-bis(isocyanatomethyl)cyclohexane, bis(4-isocyanatophenyl)methane, isophorone diisocyanate, 1,3-bis(2-isocyanato-2-propyl)benzene, 2,2-bis(4-isocyanatophenyl)hexafluoropropane, dicyclohexylmethane-4,4′-diisocyanate, and the like.
<Dicarboxylic acids> oxalic acid, malonic acid, succinic acid, glutaric acid, adipic acid, suberic acid, azelaic acid, sebacic acid, undecanedioic acid, dodecanedioic acid, terephthalic acid, isophthalic acid, 5-hydroxyisophthalic acid, 2-chloroterephthalic acid, 2-methylterephthalic acid, 5-methylisophthalic acid, 5-sodium sulfoisophthalic acid, hexahydroterephthalic acid, hexahydroisophthalic acid, cyclohexanedicarboxylic acid, biphenyldicarboxylic acid, naphthalenedicarboxylic acid, benzophenonedicarboxylic acid, furandicarboxylic acid, 4,4′-dicarboxydiphenyl ether, 4,4′-dicarboxydiphenyl sulfide, and the like.
<Acid chlorides> acetyl chloride, acrylic acid chloride, methacrylic acid chloride, malonyl chloride, succinic acid dichloride, diglycolyl chloride, glutaric acid dichloride, suberic acid dichloride, sebacic acid dichloride, adipic acid dichloride, dodecandioyl dichloride, azelaic acid chloride, 2,5-furandicarbonyl dichloride, phthaloyl chloride, isophthaloyl chloride, terephthaloyl chloride, trimesic acid chloride, bis(4-chlorocarbonylphenyl) ether, 4,4′-diphenyldicarbonyl chloride, 4,4′-azodibenzoyl dichloride, and the like.
<Lactam> ε-caprolactam, ω-undecanelactam, ω-laurolactam, and the like.

### [Polyimide Resin]

Examples of polyimide resins include, but are not limited to, reaction products of the diamines and the tetracarboxylic dianhydrides shown below. These may be used alone or in combination.
<Tetracarboxylic acid dianhydrides> 4,4′-(hexafluoroisopropylidene)diphthalic anhydride, 5-(2,5-dioxotetrahydro-3-furanyl)-3-methyl-cyclohexene-1,2-dicarboxylic anhydride, pyromellitic dianhydride, 1,2,3,4-benzenetetracarboxylic dianhydride, 3,3′,4,4′-benzophenonetetracarboxylic dianhydride, 2,2′,3,3′-benzophenonetetracarboxylic dianhydride, 3,3′,4,4′-biphenyltetracarboxylic dianhydride, 3,3′,4,4′-diphenylsulfonate tetracarboxylic dianhydride, 2,2′,3,3′-biphenyltetracarboxylic dianhydride, methylene-4,4′-diphthalic dianhydride, 1,1-ethylidene-4,4′-diphthalic dianhydride, 2,2′-propylidene-4,4′-diphthalic dianhydride, 1,2-ethylene-4,4′-diphthalic dianhydride, 1,3-trimethylene-4,4′-diphthalic dianhydride, 1,4-tetramethylene-4,4′-diphthalic dianhydride, 1,5-pentamethylene-4,4′-diphthalic dianhydride, 4,4′-oxydiphthalic dianhydride anhydride, thio-4,4′-diphthalic dianhydride, sulfonyl-4,4′-diphthalic dianhydride, 1,3-bis(3,4-dicarboxyphenyl)benzene dianhydride, 1,3-bis(3,4-dicarboxyphenoxy)benzene dianhydride, 1,4-bis(3,4-dicarboxyphenoxy)benzene dianhydride, 1,3-bis[2-(3,4-dicarboxyphenyl)-2-propyl]benzene dianhydride, 1,4-bis[2-(3,4-dicarboxyphenyl)-2-propyl]benzene dianhydride, bis[3-(3,4-dicarboxyphenoxy)phenyl]methane dianhydride, bis[4-(3,4-dicarboxyphenoxy)phenyl]methane dianhydride, 2,2-bis[3-(3,4-dicarboxyphenoxy)phenyl]propane dianhydride, 2,2-bis[4-(3,4-dicarboxyphenoxy)phenyl]propane dianhydride, bis(3,4-dicarboxyphenoxy)dimethylsilane dianhydride, 1,3-bis(3,4-dicarboxyphenyl)-1,1,3,3-tetramethyldisiloxane dianhydride, 2,3,6,7-Naphthalene tetracarboxylic dianhydride, 1,4,5,8-naphthalene tetracarboxylic dianhydride, 1,2,5,6-naphthalene tetracarboxylic dianhydride, 3,4,9,10-perylene tetracarboxylic dianhydride, 2,3,6,7-anthracene tetracarboxylic dianhydride, 1,2,7,8-phenanthrene tetracarboxylic dianhydride, ethylene tetracarboxylic dianhydride, 1,2,3,4-butane tetracarboxylic dianhydride, 1,2,3,4-cyclobutane tetracarboxylic dianhydride, cyclopentane tetracarboxylic dianhydride, cyclohexane-1,2,3,4-tetracarboxylic acid dianhydride, cyclohexane-1,2,4,5-tetracarboxylic acid dianhydride, 3,3′,4,4′-bicyclohexyltetracarboxylic acid dianhydride, carbonyl-4,4′-bis(cyclohexane-1,2-dicarboxylic acid) dianhydride, methylene-4,4′-bis(cyclohexane-1,2-dicarboxylic acid) dianhydride, 1,2-ethylene-4,4′-bis(cyclohexane-1,2-dicarboxylic acid) dianhydride, 1,1-ethylidene-4,4′-bis(cyclohexane-1,2-dicarboxylic acid) dianhydride, 2,2-propylidene-4,4′-bis(cyclohexane-1,2-dicarboxylic acid) dianhydride, oxy-4,4′-bis(cyclohexane-1,2-dicarboxylic acid) dianhydride, thio-4,4′-bis(cyclohexane-1,2-dicarboxylic acid) dianhydride, sulfonyl-4,4′-bis(cyclohexane-1,2-dicarboxylic acid) dianhydride, bicyclo[2,2,2]oct-7-ene-2,3,5,6-tetracarboxylic acid dianhydride, rel-[1S,5 R,6R]-3-oxabicyclo[3,2,1]octane-2,4-dione-6-spiro-3′-(tetrahydrofuran-2′,5′-dione), 4-(2,5-dioxotetrahydrofuran-3-yl)-1,2,3,4-tetrahydronaphthalene-1,2-dicarboxylic anhydride, ethylene glycol-bis-(3,4-dicarboxylic anhydride phenyl)ether, 4,4′-biphenyl bis(trimellitic acid monoester acid anhydride), 9,9′-bis(3,4-dicarboxyphenyl)fluorene dianhydride, and the like.

### [Cyanate Ester Resin]

The cyanate ester resin is a compound obtained by reacting a phenolic resin with a cyanogen halide, and specific examples thereof include, but are not limited to, dicyanatobenzene, tricyanatobenzene, dicyanatonaphthalene, dicyanatobiphenyl, 2,2′-bis(4-cyanatophenyl)propane, bis(4-cyanatophenyl)methane, bis(3,5-dimethyl-4-cyanatophenyl)methane, 2,2′-bis(3,5-dimethyl-4-cyanatophenyl)propane, 2,2′-bis(4-cyanatophenyl)ethane, 2,2′-bis(4-cyanatophenyl)hexafluoropropane, bis(4-cyanatophenyl)sulfone, bis(4-cyanatophenyl)thioether, phenol novolac cyanate, and a resin in which hydroxy groups of phenol-dicyclopentadiene co-condensates are substituted with cyanate groups. These may be used alone or in combination.

Furthermore, the cyanate ester compound, the synthesis method of which is described in JP-A-2005-264154, is particularly preferred as the cyanate ester compound because it has low moisture absorption, excellent flame retardancy, and excellent dielectric properties.

The cyanate ester resin may contain a catalyst such as zinc naphthenate, cobalt naphthenate, copper naphthenate, lead naphthenate, zinc octoate, tin octoate, lead acetylacetonate, or dibutyltin maleate, if necessary, to trimerize the cyanate group to form a sym-triazine ring.

The catalyst is preferably used in an amount of 0.0001 to 0.10 parts by mass, and more preferably 0.00015 to 0.0015 parts by mass, per 100 parts by mass of the total of the curable resin composition containing the cyanate ester resin and the curable resin of this embodiment.

### [Polybutadiene and its Modified Products]

The polybutadiene and its modified products are polybutadiene or compounds having a structure derived from polybutadiene in the molecule. The unsaturated bonds in the polybutadiene-derived structure may be partially or entirely converted to single bonds by hydrogenation.

Examples of polybutadiene and modified products thereof include, but are not limited to, polybutadiene, hydroxy-terminated polybutadiene, (meth)acrylate-terminated polybutadiene, carboxylic acid-terminated polybutadiene, amine-terminated polybutadiene, styrene-butadiene rubber, and the like. These may be used alone or in combination. Of these, polybutadiene or styrene-butadiene rubber is preferred from the viewpoint of dielectric properties. Examples of styrene-butadiene rubber (SBR) include RICON-100, RICON-181, RICON-184 (all manufactured by Cray Valley Corporation), 1,2-SBS (manufactured by Nippon Soda Co., Ltd.), and examples of polybutadiene include B-1000, B-2000, B-3000 (all manufactured by Nippon Soda Co., Ltd.), and the like. The molecular weight of polybutadiene and styrene-butadiene rubber is preferably a weight average molecular weight of 500 to 10,000, more preferably 750 to 7,500, and even more preferably 1,000 to 5,000. Below the lower limit of the above range, the amount of volatilization is large, making it difficult to adjust the solid content during preparation of the prepreg, while above the upper limit of the above range, compatibility with other curable resins is deteriorated.

### [Polystyrene and its Modified Products]

Polystyrene and modified products thereof are polystyrene or compounds having a structure derived from polystyrene in the molecule.

Examples of polystyrene and modified products thereof include, but are not limited: polystyrene, styrene-2-isopropenyl-2-oxazoline copolymers (Epocross RPS-1005, RP-61, both manufactured by Nippon Shokubai Co., Ltd.), SEP (styrene-ethylene-propylene copolymer: SEPTON 1020, manufactured by Kuraray Co., Ltd.), SEPS (styrene-ethylene-propylene-styrene copolymer: SEPTON 2002, SEPTON 2004F, SEPTON 2005, SEPTON 2006, SEPTON 2063, SEPTON 2104, all manufactured by Kuraray Co., Ltd.), SEEPS (styrene-ethylene/ethylene-propylene-styrene block copolymers: SEPTON 4003, SEPTON 4044, SEPTON 4055, SEPTON 4077, SEPTON 4099, all manufactured by Kuraray Co., Ltd.), SEBS (styrene-ethylene-butylene-styrene block copolymers: SEPTON 8004, SEPTON 8006, SEPTON 8007L, SEEPS-OH (a compound having a hydroxy group at the end of a styrene-ethylene/ethylene propylene-styrene block copolymer: SEPTON HG252, manufactured by Kuraray Co., Ltd.), SIS (styrene-isoprene-styrene block copolymer: SEPTON 5125, SEPTON 5127, both manufactured by Kuraray Co., Ltd.), hydrogenated SIS (hydrogenated styrene-isoprene-styrene block copolymer: Hybler 7125F, Hybler 7311F, both manufactured by Kuraray Co., Ltd.), SIBS (styrene-isobutylene-styrene block copolymer: SIBSTAR 073T, SIBSTAR 102T, SIBSTAR 103T (all manufactured by Kaneka Corporation), SEPTON V9827 (manufactured by Kuraray Co., Ltd.)). These block copolymers may be used alone or in combination. Polystyrene and its modified products are preferably those that do not have unsaturated bonds, since they have higher heat resistance and are less susceptible to oxidation degradation. The weight-average molecular weight of polystyrene and its modified products is not particularly limited as long as it is 10,000 or more, but if it is too large, the compatibility with not only polyphenylene ether compounds, but also low molecular weight components with a weight-average molecular weight of about 50 to 1,000 and oligomer components with a weight-average molecular weight of about 1,000 to 5,000 deteriorates, making it difficult to ensure mixing and solvent stability, so it is preferably about 10,000 to 300,000.

### [Inorganic Filler]

The curable resin composition of the present embodiment may contain an inorganic filler. Examples of inorganic fillers include powders such as fused silica, crystalline silica, porous silica, alumina, zircon, calcium silicate, calcium carbonate, quartz powder, silicon carbide, silicon nitride, boron nitride, zirconia, aluminum nitride, graphite, forsterite, steatite, spinel, mullite, titania, talc, clay, iron oxide, asbestos, and glass powder, and inorganic fillers obtained by making these into a spherical or crushed shape, but are not limited thereto. In addition, these may be used alone or in combination.

When a curable resin composition for semiconductor encapsulation is obtained, the amount of the inorganic filler used is preferably 80 to 92 parts by mass, and more preferably 83 to 90 parts by mass, based on 100 parts by mass of the curable resin composition. When a curable resin composition for an interlayer insulating layer forming material, or a substrate material such as a copper-clad laminate, prepreg, or RCC is obtained, the amount of the inorganic filler used is preferably 5 to 80 parts by mass, and more preferably 10 to 60 parts by mass, based on 100 parts by mass of the curable resin composition.

### [Curing Accelerator]

The curable resin composition of the present embodiment can also have improved curability by adding a curing accelerator. As the curing accelerator, an anionic curing accelerator that accelerates the curing reaction by generating anions upon heating, or a cationic curing accelerator that accelerates the curing reaction by generating cations upon heating, is preferred.

Examples of the anionic curing accelerator include: imidazoles such as 2-methylimidazole, 2-ethylimidazole, and 2-ethyl-4-methylimidazole; trialkylamines such as triethylamine and tributylamine; 4-dimethylaminopyridine, benzyldimethylamine, 2,4,6-tris(dimethylaminomethyl) phenol, and 1,8-diazabicyclo(5,4,0)-undecene, with 4-dimethylaminopyridine and 1,8-diazabicyclo(5,4,0)-undecene being preferred. Other examples include, but are not limited to: phosphines such as triphenylphosphine; quaternary ammonium salts such as tetrabutylammonium salts, triisopropylmethylammonium salts, trimethyldecanylammonium salts, cetyltrimethylammonium salts, and hexadecyltrimethylammonium hydroxide. These may be used alone or in combination.

Examples of the cationic curing accelerator include: quaternary phosphonium salts such as triphenylbenzylphosphonium salt, triphenylethylphosphonium salt, and tetrabutylphosphonium salt (the counter ion of the quaternary salt may be a halogen, an organic acid ion, a hydroxide ion, or the like, and is not particularly specified, but an organic acid ion or a hydroxide ion is particularly preferred); transition metal compounds (transition metal salts) such as tin octylate, zinc carboxylate (zinc 2-ethylhexanoate, zinc stearate, zinc behenate, zinc myristate), and zinc phosphate (zinc octylphosphate, zinc stearylphosphate), but are not limited thereto. Furthermore, these may be used alone or in combination.

The amount of the curing accelerator to be added is 0.01 to 5.0 parts by mass based on 100 parts by mass of the curable resin of the present embodiment, as required.

### [Polymerization Initiator]

The curable resin composition of the present embodiment can also improve the curability by adding a polymerization initiator. The polymerization initiator is a compound capable of polymerizing an olefin functional group such as an ethylenically unsaturated bond, and examples of the polymerization initiator include an olefin metathesis polymerization initiator, an anionic polymerization initiator, a cationic polymerization initiator, and a radical polymerization initiator. Among these, it is preferable to use a radical polymerization initiator having curability and moderate stability. The radical polymerization initiator is a compound that generates radicals by heating and starts a chain polymerization reaction. Examples of radical polymerization initiators that can be used include organic peroxides, azo compounds, and benzopinacoles, and it is preferable to use an organic peroxide because it has little effect on curing temperature control, outgassing suppression, and electrical properties of decomposition products.

Examples of the organic peroxides include, but are not limited to: ketone peroxides such as methyl ethyl ketone peroxide and acetylacetone peroxide; diacyl peroxides such as benzoyl peroxide; dialkyl peroxides such as dicumyl peroxide and 1,3-bis-(t-butylperoxyisopropyl)-benzene; peroxyketals such as t-butylperoxybenzoate and 1,1-di-t-butylperoxycyclohexane; alkyl peresters such as α-cumylperoxyneodecanoate, t-butylperoxyneodecanoate, t-butylperoxypivalate, 1,1,3,3-tetramethylbutylperoxy-2-ethylhexanoate, t-amylperoxy-2-ethylhexanoate, t-butylperoxy-2-ethylhexanoate, t-amylperoxy-3,5,5-trimethylhexanoate, t-butylperoxy-3,5,5-trimethylhexanoate, t-amyl peroxybenzoate; peroxycarbonate such as di-2-ethylhexyl peroxydicarbonate, bis(4-t-butylcyclohexyl)peroxydicarbonate, t-butylperoxyisopropyl carbonate, 1,6-bis(t-butylperoxycarbonyloxy)hexane; t-butyl hydroperoxide, cumene hydroperoxide, t-butyl peroxyoctoate, lauroyl peroxide, etc. These may be used alone or in combination. Among the above organic peroxides, ketone peroxides, diacyl peroxides, hydroperoxides, dialkyl peroxides, peroxyketals, alkyl peresters, peroxycarbonates, etc. are preferred, with dialkyl peroxides being more preferred.

Examples of the azo-based compound include, but are not limited to, azobisisobutyronitrile, 4,4′-azobis(4-cyanovaleric acid), 2,2′-azobis(2,4-dimethylvaleronitrile), etc. These may be used alone or in combination.

The amount of the polymerization initiator added is preferably 0.01 to 5 parts by mass, and particularly preferably 0.01 to 3 parts by mass, relative to 100 parts by mass of the curable resin composition. If the amount of the polymerization initiator used is less than 0.01 part by mass, the molecular weight may not be sufficiently extended during the polymerization reaction, and if it is more than 5 parts by mass, the dielectric properties such as the dielectric constant and the dielectric loss tangent may be impaired.

### [Polymerization Inhibitor]

The curable resin composition of the present embodiment may contain a polymerization inhibitor. By containing a polymerization inhibitor, storage stability is improved and the reaction initiation temperature can be controlled. By controlling the reaction initiation temperature, it becomes easy to ensure fluidity, impregnation into glass cloth and the like is not impaired, and B-stage such as prepreg formation is facilitated. If the polymerization reaction proceeds too much during prepreg formation, problems such as difficulty in lamination during the lamination process are likely to occur.

The polymerization inhibitor may be added when synthesizing the curable resin of the present embodiment, or may be added after synthesis. The amount of the polymerization inhibitor used is 0.008 to 1 part by mass, preferably 0.01 to 0.5 parts by mass, based on 100 parts by mass of the curable resin of the present embodiment.

Examples of the polymerization inhibitor include phenol-based, sulfur-based, phosphorus-based, hindered amine-based, nitroso-based, and nitroxyl radical-based. The polymerization inhibitor may be used alone or in combination. Among these, in the present embodiment, the phenol-based, hindered amine-based, nitroso-based, and nitroxyl radical-based are preferred.

Examples of the phenol-based polymerization inhibitor include, but are not limited thereto: monophenols such as 2,6-di-t-butyl-p-cresol, butylated hydroxyanisole, 2,6-di-t-butyl-p-ethylphenol, stearyl-β-(3,5-di-t-butyl-4-hydroxyphenyl)propionate, isooctyl-3-(3,5-di-t-butyl-4-hydroxyphenyl)propionate, 2,4-bis-(n-octylthio)-6-(4-hydroxy-3,5-di-t-butylanilino)-1,3,5-triazine, and 2,4-bis[(octylthio)methyl]-o-cresol; bisphenols such as 2,2′-methylenebis(4-methyl-6-t-butylphenol), 2,2′-methylenebis(4-ethyl-6-t-butylphenol), 4,4′-thiobis(3-methyl-6-t-butylphenol), 4,4′-butylidenebis(3-methyl-6-t-butylphenol), triethylene glycol-bis[3-(3-t-butyl-5-methyl-4-hydroxyphenyl)propionate], 1,6-hexanediol-bis[3-(3,5-di-t-butyl-4-hydroxyphenyl)propionate], N,N′-hexamethylenebis(3,5-di-t-butyl-4-hydroxy-hydrocinnamamide), 2,2-thio-diethylenebis[3-(3,5-di-t-butyl-4-hydroxyphenyl)propionate], 3,5-di-t-butyl-4-hydroxybenzylphosphonate-diethyl ester, 3,9-bis[1,1-dimethyl-2-{-(3-t-butyl-4-hydroxy-5-methylphenyl)propionyloxy}ethyl]-2,4,8,10-tetraoxaspiro[5,5]undecane, bis(3,5-di-t-butyl-4-hydroxybenzylsulfonate ethyl)calcium; and polymeric phenols such as 1,1,3-tris(2-methyl-4-hydroxy-5-t-butylphenyl)butane, 1,3,5-trimethyl-2,4,6-tris(3,5-di-t-butyl-4-hydroxybenzyl)benzene, tetrakis-[methylene-3-(3′,5′-di-t-butyl-4′-hydroxyphenyl)propionate]methane, bis[3,3′-bis-(4′-hydroxy-3′-t-butylphenyl)butyric acid]glycol ester, tris-(3,5-di-t-butyl-4-hydroxybenzyl)-isocyanurate, 1,3,5-tris(3′,5′-di-t-butyl-4′-hydroxybenzyl)-S-triazine-2,4,6-(1H,3H,5H)trione, tocopherol.

Examples of the sulfur-based polymerization inhibitor include, but are not limited to, dilauryl-3,3′-thiodipropionate, dimyristyl-3,3′-thiodipropionate, and distearyl-3,3′-thiodipropionate.

Examples of the phosphorus-based polymerization inhibitor include, but are not hinted to: phosphites such as triphenyl phosphite, diphenyl isodecyl phosphite, phenyl diisodecyl phosphite, tris(nonylphenyl)phosphite, diisodecyl pentaerythritol phosphite, tris (2,4-di-t-butylphenyl)phosphite, cyclic neopentane tetrayl bis(octadecyl)phosphite, cyclic neopentane tetrayl bis(2,4-di-t-butylphenyl)phosphite, cyclic neopentane tetrayl bis(2,4-di-t-butyl-4-methylphenyl)phosphite, bis[2-t-butyl-6-methyl-4-{2-(octadecyloxycarbonyl)ethyl}phenyl]hydrogen phosphite; and oxaphosphaphenanthrene oxides such as 9,10-dihydro-9-oxa-10-phosphaphenanthrene-10-oxide, 10-(3,5-di-t-butyl-4-hydroxybenzyl)-9,10-dihydro-9-oxa-10-phosphaphenanthrene-10-oxide, and 10-decyloxy-9,10-dihydro-9-oxa-10-phosphaphenanthrene-10-oxide.

Examples of the hindered amine polymerization inhibitor include, but are not limited to: ADK STAB LA-40MP, ADK STAB LA-40Si, ADK STAB LA-402AF, ADK STAB LA-87, ADK STAB LA-82, ADK STAB LA-81, ADK STAB LA-77Y, ADK STAB LA-77G, ADK STAB LA-72, ADK STAB LA-68, ADK STAB LA-63P, ADK STAB LA-57, and ADK STAB LA-52 (all manufactured by ADEKA Corporation); Chimassorb 2020FDL, Chimassorb 944FDL, Chimassorb 944LD, Tinuvin 622SF, Tinuvin PA144, Tinuvin 765, Tinuvin 770DF, Tinuvin XT55FB, Tinuvin 111FDL, Tinuvin 783FDL, and Tinuvin 791FB (all manufactured by BASF).

Examples of the nitroso-based polymerization inhibitor include, but are not limited to, p-nitrosophenol, N-nitrosodiphenylamine, ammonium salt of N-nitrosophenylhydroxyamine (cupferron). Among these, the ammonium salt of N-nitrosophenylhydroxyamine (cupferron) is preferred.

Examples of the nitroxyl radical polymerization inhibitor include di-tert-butyl nitroxide, 2,2,6,6-tetramethylpiperidine-1-oxyl, 4-hydroxy-2,2,6,6-tetramethylpiperidine-1-oxyl, 4-oxo-2,2,6,6-tetramethylpiperidine-1-oxyl, 4-amino-2,2,6,6-tetramethylpiperidine-1-oxyl, 4-methoxy-2,2,6,6-tetramethylpiperidine-1-oxyl, 4-acetoxy-2,2,6,6-tetramethylpiperidine-1-oxyl, 4-benzoyloxy-2,2,6,6-tetramethylpiperidine-1-oxyl, and the like, but are not limited thereto.

### [Flame Retardant]

The curable resin composition of the present embodiment may contain a flame retardant. Examples of the flame retardant include halogen-based flame retardants, inorganic flame retardants (antimony compounds, metal hydroxides, nitrogen compounds, boron compounds, etc.), and phosphorus-based flame retardants. From the viewpoint of achieving halogen-free flame retardancy, phosphorus-based flame retardants are preferred.

The phosphorus-based flame retardant may be of a reactive type or an additive type. Specific examples include, but are not limited: phosphoric acid esters such as trimethyl phosphate, triethyl phosphate, tricresyl phosphate, trixylenyl phosphate, cresyl diphenyl phosphate, cresyl-2,6-dixylenyl phosphate, 1,3-phenylene bis(dixylenyl phosphate), 1,4-phenylene bis(dixylenyl phosphate), and 4,4′-biphenyl(dixylenyl phosphate); phosphanes such as 9,10-dihydro-9-oxa-10-phosphaphenanthrene-10-oxide and 10(2,5-dihydroxyphenyl)-10H-9-oxa-10-phosphaphenanthrene-10-oxide; phosphorus-containing epoxy compounds obtained by reacting epoxy resins with active hydrogen of the phosphanes, red phosphorus, and the like. In addition, these may be used alone or in combination. Of the above-listed substances, phosphate esters, phosphanes or phosphorus-containing epoxy compounds are preferred, with 1,3-phenylenebis(dixylenyl phosphate), 1,4-phenylenebis(dixylenyl phosphate), 4,4′-biphenyl(dixylenyl phosphate) or phosphorus-containing epoxy compounds being particularly preferred.

The content of the flame retardant is preferably in the range of 0.1 to 0.6 parts by mass, assuming that the total of non-volatile matters in the curable resin composition excluding the inorganic filler is 100 parts by mass. If the content is less than 0.1 part by mass, the flame retardancy may be insufficient, and if the content is more than 0.6 part by mass, the moisture absorption and dielectric properties of the cured product may be adversely affected.

### [Light Stabilizer]

The curable resin composition of the present embodiment may contain a light stabilizer. As the light stabilizer, a hindered amine light stabilizer (HALS) or the like is preferable. Examples of the HALS include, but are not limited to: a reaction product of dibutylamine, 1,3,5-triazine and N,N′-bis(2,2,6, 6-tetramethyl-4-piperidyl-1,6-hexamethylenediamine with N-(2,2,6,6-tetramethyl-4-piperidyl)butylamine, a poly condensation product of dimethyl succinate and 1-(2-hydroxyethyl)-4-hydroxy-2,2,6,6-tetramethylpiperidine, poly[{6-(1,1,3,3-tetramethylbutyl)amino-1,3,5-triazine-2,4-diyl}{(2,2,6,6-tetramethyl-4-piperidyl)imino}hexamethylene{(2,2,6,6-tetramethyl-4-piperidyl)imino}], bis(1,2,2,6,6-pentamethyl-4-piperidyl)[[3,5-bis(1,1-dimethylethyl)-4-hydroxyphenyl]methyl]butyl malonate, bis(2,2,6,6-tetramethyl-4-piperidyl)sebacate, bis(1,2,2,6,6-pentamethyl-4-piperidyl)sebacate, bis(1-octyloxy-2,2,6,6-tetramethyl-4-piperidyl)sebacate, 2-(3,5-di-t-butyl-4-hydroxybenzyl)-2-n-butylmalonate bis(1,2,2,6,6-pentamethyl-4-piperidyl). These may be used alone or in combination.

The content of the light stabilizer is preferably in the range of 0.001 to 10 parts by mass, assuming that the total nonvolatile content excluding the inorganic filler in the curable resin composition is 100 parts by mass. If the content is less than 0.001 part by mass, the light stabilizing effect may be insufficient, and if the content is more than 10 parts by mass, the moisture absorption and dielectric properties of the cured product may be adversely affected.

### [Binder Resin]

The curable resin composition of the present embodiment may use a binder resin. Examples of the binder resin include, but are not limited to, butyral resins, acetal resins, acrylic resins, epoxy-nylon resins, NBR-phenolic resins, epoxy-NBR resins, and silicone resins. These may be used alone or in combination.

The amount of the binder resin is preferably within a range that does not impair the flame retardancy and heat resistance of the cured product, and is preferably 0.05 to 50 parts by mass, and more preferably 0.05 to 20 parts by mass, relative to 100 parts by mass of the total amount of the curable resin composition.

### [Additives]

The curable resin composition of the present embodiment may contain additives. Examples of additives include modified acrylonitrile copolymers, polyethylene, fluororesins, silicone gels, silicone oils, surface treatment agents for fillers such as silane coupling agents, release agents, and colorants such as carbon black, phthalocyanine blue, and phthalocyanine green.

The amount of the additive is preferably 30 parts by mass or less, more preferably 20 parts by mass or less, and particularly preferably 10 parts by mass or less, based on 100 parts by mass of the curable resin composition.

The curable resin composition of the present embodiment can be obtained by preparing the above-mentioned components in a predetermined ratio, and the curing reaction proceeds sufficiently by curing for 1 to 15 hours at 150 to 250° C., to obtain the cured product of the present embodiment. Alternatively, the components of the curable resin composition can be uniformly dispersed or dissolved in a solvent or the like, and the composition may be cured after the solvent is removed.

The method for preparing the curable resin composition of the present embodiment is not particularly limited, but each component may be mixed uniformly or may be prepolymerized. For example, a mixture containing the components represented by the formula (1) is heated in the presence or absence of a curing accelerator or a polymerization initiator, and in the presence or absence of a solvent to form a prepolymer. Similarly, an amine compound, a compound having an ethylenically unsaturated bond, a maleimide compound, a cyanate ester compound, polybutadiene and its modified products, polystyrene and its modified products, inorganic fillers, and other additives may be added to form a prepolymer. The mixing or prepolymerization of each component is carried out using, for example, an extruder, a kneader, a roll, etc. in the absence of a solvent, and a reaction kettle with a stirrer, etc. in the presence of a solvent. By prepolymerization, the tackiness after B-stage and the storage stability in the varnish can be improved.

As a method of uniform mixing, the mixture is kneaded at a temperature in the range of 50 to 100° C. using a device such as a kneader, roll, or planetary mixer to obtain a uniform resin composition. The obtained resin composition is crushed and then molded into a cylindrical tablet using a molding machine such as a tablet machine, or into a granular powder or powder molded body, or these compositions can be melted on a surface support and molded into a sheet having a thickness of 0.05 mm to 10 mm to obtain a molded curable resin composition. The obtained molded body is a non-sticky molded body at 0 to 20° C., and even if stored at −25 to 0° C. for one week or more, the flowability and curability are hardly reduced.

The obtained molded article can be molded into a cured product using a transfer molding machine or a compression molding machine.

The curable resin composition of the present embodiment can be made into a varnish-like composition (hereinafter, simply referred to as varnish) by adding an organic solvent. The curable resin composition of the present embodiment can be dissolved in a solvent such as toluene, xylene, acetone, methyl ethyl ketone, methyl isobutyl ketone, dimethylformamide, dimethylacetamide, or N-methylpyrrolidone as necessary to form a varnish, which is then impregnated into a substrate such as glass fiber, carbon fiber, polyester fiber, polyamide fiber, alumina fiber, or paper, and dried by heating to obtain a prepreg, which is then hot-press molded to obtain a cured product of the curable resin composition of the present embodiment. The solvent used in this case is in an amount that occupies 10 to 70% by weight, preferably 15 to 70% by weight, in the mixture of the curable resin composition of the present embodiment and the solvent. In addition, if the composition is in a liquid state, a cured product of the curable resin containing carbon fiber can be obtained as it is, for example, by the RTM method.

The curable resin composition of the present embodiment can also be used as a modifier for a film-type composition. Specifically, it can be used to improve flexibility and the like in the B-stage. Such a film-type resin composition can be obtained as a sheet-like adhesive by applying the curable resin composition of the present embodiment as a varnish onto a release film, removing the solvent under heating, and then performing B-stage formation. This sheet-like adhesive can be used as an interlayer insulating layer in a multilayer substrate or the like.

The curable resin composition of the present embodiment can be heated and melted to reduce the viscosity, and impregnated into reinforced fibers such as glass fibers, carbon fibers, polyester fibers, polyamide fibers, and alumina fibers to obtain a prepreg. Specific examples thereof include glass fibers such as E glass cloth, D glass cloth, S glass cloth, Q glass cloth, spherical glass cloth, NE glass cloth, and T glass cloth, inorganic fibers other than glass, and organic fibers such as polyparaphenylene terephthalamide (Kevlar (registered trademark), manufactured by DuPont), wholly aromatic polyamide, polyester, polyparaphenylene benzoxazole, polyimide, and carbon fibers, but are not particularly limited thereto. The shape of the substrate is not particularly limited, but examples thereof include woven fabric, nonwoven fabric, roving, chopped strand mat, and the like. In addition, as the weaving method of the woven fabric, plain weave, saddle weave, twill weave, and the like are known, and these known weaves can be appropriately selected and used depending on the intended use and performance. In addition, woven fabrics that have been subjected to fiber opening treatment and glass woven fabrics that have been surface-treated with a silane coupling agent or the like are preferably used. The thickness of the substrate is not particularly limited, but is preferably about 0.01 to 0.4 mm. A prepreg can also be obtained by impregnating reinforcing fibers with the varnish and drying the fibers by heating.

Moreover, a laminate can be manufactured using the prepreg. The laminate is not particularly limited as long as it has one or more prepregs, and may have any other layer. The manufacturing method of the laminate can be appropriately applied by a generally known method, and is not particularly limited. For example, when molding a metal foil-clad laminate, a multi-stage press machine, a multi-stage vacuum press machine, a continuous molding machine, an autoclave molding machine, etc. can be used, and the prepregs are laminated together and heated and pressurized to obtain a laminate. At this time, the heating temperature is not particularly limited, but is preferably 65 to 300° C., and more preferably 120 to 270° C. In addition, the pressure to be applied is not particularly limited, but if the pressure is too high, it is difficult to adjust the solid content of the resin of the laminate, and the quality is not stable, and if the pressure is too low, air bubbles and adhesion between the laminates are deteriorated, so that 2.0 to 5.0 MPa is preferable, and 2.5 to 4.0 MPa is more preferable. The laminate of this embodiment can be suitably used as a metal foil-clad laminate described later by providing a layer made of metal foil.

The prepreg is cut into a desired shape and laminated with copper foil or the like as necessary. The laminate is then heated and cured while applying pressure thereto by press molding, autoclave molding, sheet winding molding or the like, to obtain an electrical and electronic laminate (printed wiring board) or a carbon fiber reinforced material.

The curable resin composition of this embodiment can also be made into a resin sheet. As a method for obtaining a resin sheet from the curable resin composition of this embodiment, for example, a method of applying the curable resin composition onto a support film (support), drying it, and forming a resin composition layer on the support film can be mentioned. When the curable resin composition of this embodiment is used for a resin sheet, it is essential that the film softens under the temperature conditions (70° C. to 140° C.) of lamination in the vacuum lamination method, and simultaneously with lamination of the circuit board, exhibits a fluidity (resin flow) that allows resin filling in via holes or through holes present in the circuit board, and it is preferable to blend each of the components so as to express such characteristics. In addition, in the obtained resin sheet or circuit board (copper-clad laminate, etc.), a phenomenon that locally different characteristic values are exhibited due to phase separation or the like is not caused, and a certain performance is expressed at any part, so that a uniform appearance is required.

Here, the diameter of the through-holes in the circuit board is 0.1 to 0.5 mm, and the depth is 0.1 to 1.2 mm, and it is preferable to make it possible to fill the resin within this range. When laminating both sides of the circuit board, it is preferable to fill about ½ of the through-holes.

A specific method for producing the resin sheet includes preparing a resin composition varnished by blending an organic solvent, applying the varnished resin composition to the surface of a support film (Y), and then drying the organic solvent by heating or blowing hot air or the like to form a resin composition layer (X).

The organic solvent used here is preferably, for example, a ketone such as acetone, methyl ethyl ketone, cyclohexanone, etc., an acetate such as ethyl acetate, butyl acetate, cellosolve acetate, propylene glycol monomethyl ether acetate, carbitol acetate, etc., a carbitol such as cellosolve, butyl carbitol, etc., an aromatic hydrocarbon such as toluene, xylene, etc., dimethylformamide, dimethylacetamide, N-methylpyrrolidone, etc. It is also preferable to use an organic solvent in such a proportion that the nonvolatile content is 30 to 60 mass % of the total.

The thickness of the resin composition layer (X) to be formed must be equal to or greater than the thickness of the conductor layer of the circuit board to which the resin composition layer (X) is laminated. Since the thickness of the conductor layer of the circuit board is in the range of 5 to 70 μm, the thickness of the resin composition layer (X) is preferably 10 to 100 μm. The resin composition layer (X) in this embodiment may be protected with a protective film to be described later. By protecting the resin composition layer (X) with a protective film, it is possible to prevent the adhesion of dirt and the like to the surface of the resin composition layer (X) and scratches.

The support film and the protective film may be made of a polyolefin such as polyethylene, polypropylene, or polyvinyl chloride, a polyester such as polyethylene terephthalate (PET) or polyethylene naphthalate, a polycarbonate, or a polyimide, or may be a release paper or a metal foil such as a copper foil or an aluminum foil. The support film and the protective film may be subjected to a release treatment in addition to a matte treatment or a corona treatment. The thickness of the support film is not particularly limited, but is in the range of 10 to 150 μm, and preferably 25 to 50 μm. The thickness of the protective film is preferably 1 to 40 μm.

The support film (Y) is peeled off after laminating the resin composition layer (X) on a circuit board, or after forming an insulating layer by heat-curing the resin composition layer (X). If the support film (Y) is peeled off after the resin composition layer (X) constituting the resin sheet is heat-cured, adhesion of dust and the like during the curing process can be prevented. When the support film (Y) is peeled off after the resin composition layer (X) is heat-cured, the support film (Y) is previously subjected to a release treatment.

A multilayer printed circuit board can be manufactured from the resin sheet obtained as described above. For example, when the resin composition layer (X) is protected by a protective film, the protective film is peeled off from the resin composition layer (X), and then the resin composition layer (X) is laminated on one or both sides of the circuit board so as to be in direct contact with the circuit board, for example, by a vacuum lamination method. The lamination method may be a batch type or a continuous type using a roll. If necessary, the resin sheet and the circuit board may be heated (preheated) before lamination. The lamination conditions are preferably a pressure bonding temperature (lamination temperature) of 70 to 140° C., a pressure bonding pressure of 1 to 11 kgf/cm² (9.8×10⁴ to 107.9×10⁴ N/m²), and lamination is preferably performed under reduced pressure of 20 mmHg (26.7 hPa) or less.

The curable resin composition of the present embodiment can be used to manufacture a semiconductor device. Examples of the semiconductor device include: a dual in-line package (DIP), a quad flat package (QFP), a ball grid array (BGA), a chip size package (CSP), a small outline package (SOP), a thin small outline package (TSOP), a thin quad flat package (TQFP), etc.

The curable resin composition of the present embodiment and its cured product can be used in a wide range of fields. Specifically, it can be used in various applications such as molding materials, adhesives, composite materials, and paints. The cured product of the curable resin composition described in this embodiment exhibits excellent heat resistance and dielectric properties, and is therefore suitable for use in electrical and electronic components such as semiconductor element encapsulants, liquid crystal display element encapsulants, organic EL element encapsulants, laminates (printed wiring boards, BGA substrates, build-up substrates, etc.), carbon fiber reinforced plastics, glass fiber reinforced plastics, and other lightweight and high-strength structural composite materials, 3D printing, and the like.

### EXAMPLES

The present invention will now be described in more detail with reference to examples. Unless otherwise specified, all parts are by weight. However, the present invention is not limited to these examples.

Various analytical methods used in the examples are described below.

### Hydroxy Equivalent

It is measured by the following method, and the unit is g/eq.

The phenolic resin is reacted with an excess of acetic anhydride, and the amount of free acetic acid is measured by titration with a 0.5N ethanolic KOH solution using a potentiometer.
Reagent: Acetic anhydride
Catalyst: Triphenylphosphine
Solvent: Pyridine, tetrahydrofuran, propylene glycol monomethyl ether
Automatic titration device: COM-1600 manufactured by HIRANUMA Co., Ltd.
Burette: B-2000 manufactured by Hiranuma Corporation

### ¹H-NMR Analysis

Equipment: JNM-ECS400
Number of times accumulated: 16
Relaxation time: 5 seconds
Solvent: CDCl₃
Measurement temperature: Room temperature

### IR Analysis

Apparatus: Fourier transform infrared spectrophotometer (FTIR-8400, manufactured by Shimadzu Corporation)
Frequency: 400-4000 cm⁻¹

### GPC (Gel Permeation Chromatography) Analysis

Equipment: Online degassing unit (DGU-20A), liquid delivery unit (LC-20AD), autosampler (SIL-20A), photodiode array detector (SPD-M40), column oven (CTO-20A), system controller (CBM-20A), all manufactured by Shimadzu Corporation
Columns: SHODEX GPC KF-601 (2 columns), KF-602, KF-602.5, KF-603
Flow rate: 1.5 ml/min.
Column temperature: 40° C.
Solvent used: THF (tetrahydrofuran)
Detector: Differential refractometer (RID-20A), manufactured by Shimadzu Corporation

### Synthesis Example 1

In a flask equipped with a thermometer, a cooling tube, a stirrer, and a Dean-Stark tube, 109.3 parts of Neopolymer E-100 (manufactured by ENEOS Corporation, hydroxy equivalent: 729 g/eq), 270.0 parts of toluene, and 3.9 parts of methanesulfonic acid (manufactured by Junsei Chemical Co., Ltd.) were charged, and the mixture was stirred at 80° C. while bubbling nitrogen to dissolve. Next, using a dropping funnel, 6.4 parts of 35% aqueous formalin solution (manufactured by Junsei Chemical Co., Ltd.) was dropped over 30 minutes and held at 80° C. for 3 hours. Then, the reaction was carried out at 120° C. for 4 hours while distilling off water. The reaction solution in the flask was cooled to room temperature, and the reaction solution was neutralized with 5.4 parts of 30% sodium hydroxide. The reaction solution was repeatedly washed with water until the wastewater became neutral. Then, toluene and low molecular weight volatile components were distilled off under heating and reduced pressure to synthesize a phenolic resin (PH-1) represented by the above formula (2).

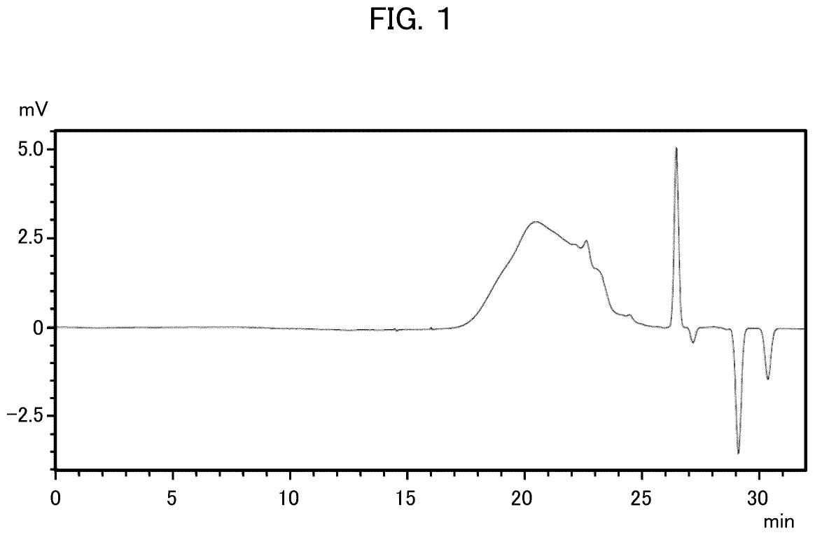

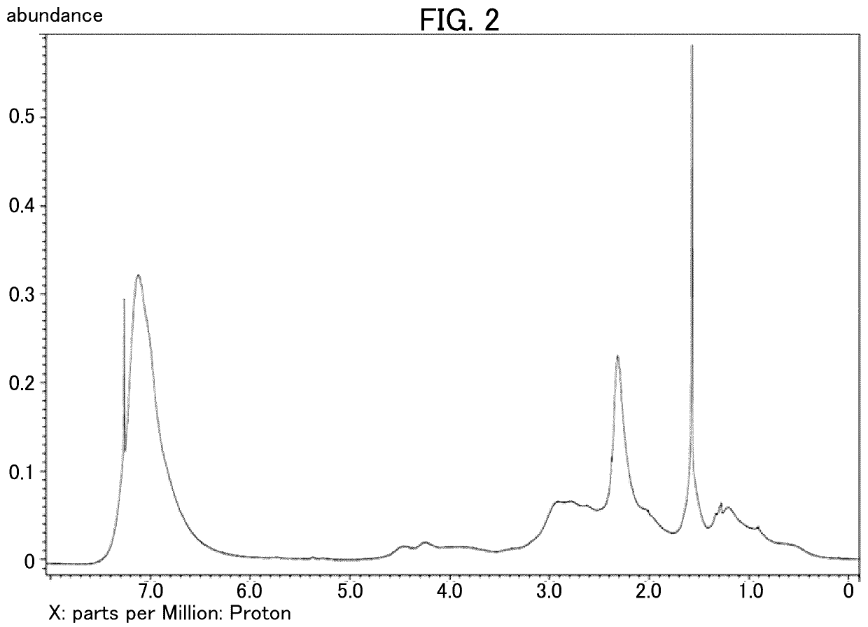

PH-1 had a hydroxy equivalent of 712 g/eq, a number average molecular weight of 893, and a weight average molecular weight of 1,291. The GPC chart is shown in FIG. 1. ¹H-NMR chart is shown in FIG. 2.

### Example 1

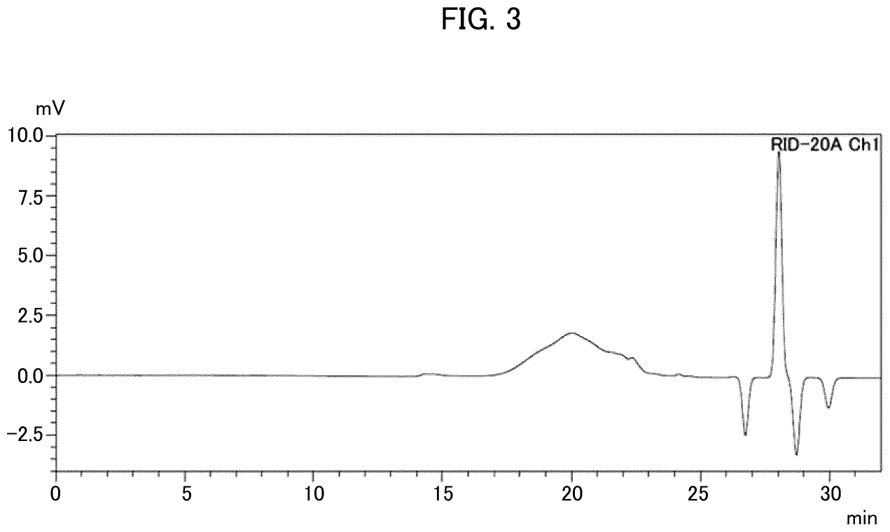

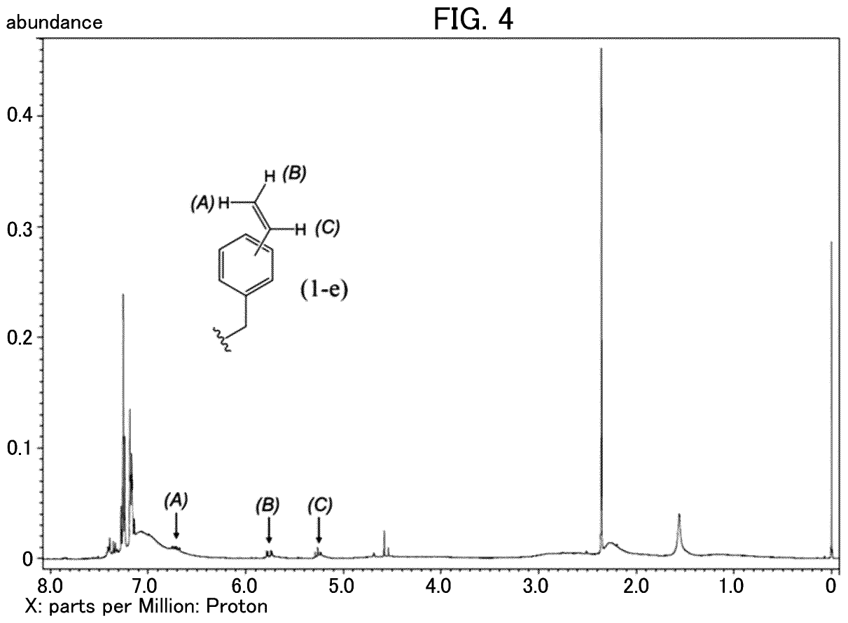

A flask equipped with a thermometer, a cooling tube, a stirrer, and a Dean-Stark tube was charged with: 23.4 parts of PH-1 obtained in Synthesis Example 1; 5.5 parts of a 30% aqueous sodium hydroxide solution; and 68.5 parts of dimethyl sulfoxide (manufactured by Toray Fine Chemicals Co., Ltd.), and stirred at 120° C. while bubbling nitrogen, and dissolved and the water in the system was distilled off. The reaction liquid in the flask was then cooled to 50° C., and 22.8 parts of toluene (manufactured by Junsei Chemical Co., Ltd.) was added to the reaction liquid and homogenized. 6.0 parts of 4-(chloromethyl)styrene (manufactured by AGC Seimi Chemical Co., Ltd., CMS-14) was added dropwise over 30 minutes using a dropping funnel, and the reaction was allowed to proceed at 50° C. for 3 hours. After the reaction was completed, 100.0 parts of toluene (manufactured by Junsei Chemical Co., Ltd.) was added, and washing with water was repeated, and it was confirmed that the wastewater became neutral. After toluene was distilled off under heating and reduced pressure, the residue was redissolved in 10 parts of toluene (manufactured by Junsei Chemical Co., Ltd.) and reprecipitated by dropping into 500 parts of methanol (manufactured by Junsei Chemical Co., Ltd.) to remove low molecular weight impurities. The GPC chart of the obtained olefin resin (S-1) is shown in FIG. 3, and the ¹H-NMR chart is shown in FIG. 4. The number average molecular weight of the olefin resin (S-1) was 1,254, the weight average molecular weight was 3,249, and the proton peaks derived from the olefin represented by formula (1-e) were confirmed at 5.2-5.3 ppm, 5.7-5.8 ppm, and 6.6-6.8 ppm.

### Example 2

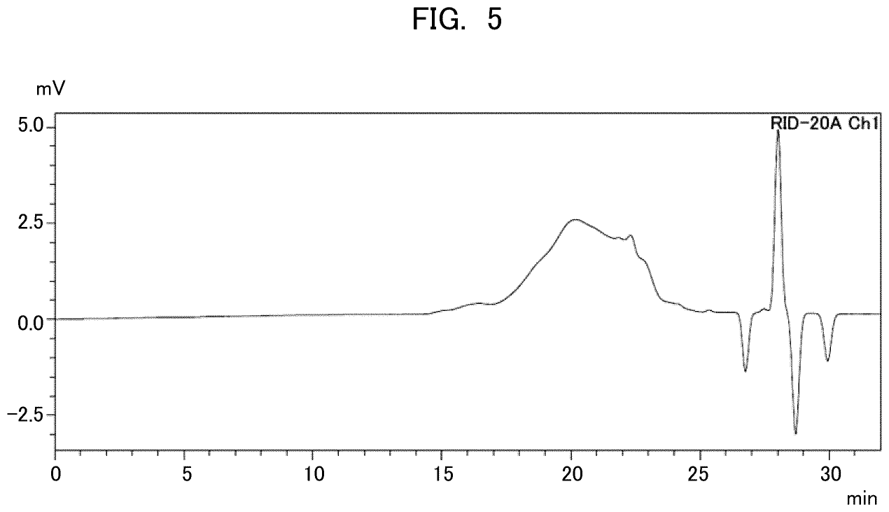

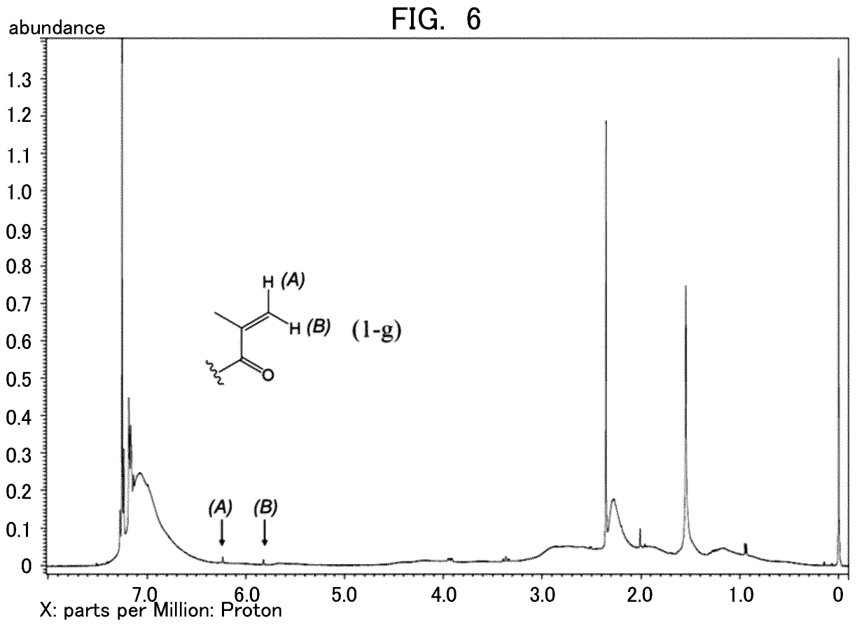

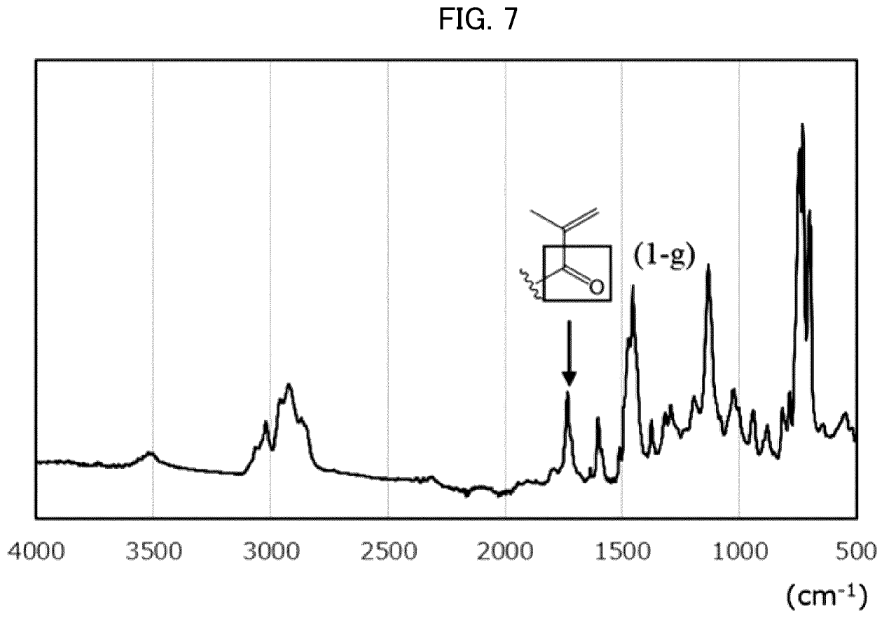

A thermometer, a cooling tube, and a stirrer were attached to the flask, and a base trap and an aspirator were connected to the cooling tube. 21.4 parts of PH-1 obtained in Synthesis Example 1, 7.3 parts of triethylamine (manufactured by Tokyo Chemical Industry Co., Ltd.), and 41.1 g of 4-methyltetrahydropyran (manufactured by Kanto Chemical Co., Ltd.) were charged into this flask, stirred, and dissolved, and 4.7 parts of methacryloyl chloride (manufactured by Tokyo Chemical Industry Co., Ltd.) were dropped into the flask over 1 hour at room temperature while collecting the generated hydrogen chloride with a base trap. Thereafter, the reaction solution in the flask was heated to 40° C., and the reaction was allowed to proceed for 6 hours while collecting the generated hydrogen chloride with a base trap. Thereafter, 100 parts of methyl isobutyl ketone and 12 parts of a 30 wt % aqueous sodium hydroxide solution were dropped into the flask to make the reaction solution basic, and the organic layer was washed five times with 50 parts of water. After distilling off the solvent under heating and reduced pressure, 80 g of toluene was added, and the excess solvent was removed again under heating and reduced pressure to obtain an olefin resin (S-2). The GPC chart of the olefin resin (S-2) is shown in FIG. 5, the ¹H-NMR chart in FIG. 6, and the IR chart in FIG. 7. The number average molecular weight of the olefin resin (S-2) was 1,053, and the weight average molecular weight was 2,112. Proton peaks derived from the olefin represented by formula (1-g) were confirmed at 5.8-5.9 ppm and 6.2-6.3 ppm, respectively. The absorption at 1732 cm⁻¹ in the IR chart is the absorption derived from the carbonyl group in the methacrylate.

### Examples 3 to 5

The olefin resin S-1 obtained in Example 1, the olefin resin S-2 obtained in Example 2, SA-9000 (polyphenylene ether resin manufactured by SABIC), OPE-2St-1200 (polyphenylene ether resin manufactured by Mitsubishi Gas Chemical Co., Ltd.), and OPE-2St-2200 (polyphenylene ether resin manufactured by Mitsubishi Gas Chemical Co., Ltd.) were mixed so that the total amount of resin was equal according to the charge table in Table 1, and a toluene solution was obtained. In Examples 3 and 4, 1 wt % of DCP (dicumyl peroxide, manufactured by Kayaku Nouryon Co., Ltd.) was further added thereto, and the mixture was thinly cast on a polyimide film, and then pre-dried at 60° C. under vacuum for about 10 minutes. The obtained dried body was ground in an agate mortar to remove toluene by low-temperature history. 0.5 g of the ground dried body was placed on copper foil, and in a state where it was sandwiched between the opposing copper foils, it was molded into a sheet of 100 mm×50 mm using a vacuum heating press, and cured under the conditions described in Table 1 to obtain a test piece. In this case, a cushion paper having a thickness of 250 μm and having a size of 100 mm×50 mm cut out in the center was used as a spacer.

### <Dielectric Constant (Dk) Test/Dielectric Loss Tangent (Df) Test>

The measurements were carried out using a coaxial resonator type dielectric constant measuring device ADMS01OC1 manufactured by AET Corporation at a measurement frequency of 10 GHz.

TABLE 1

| | Example 3 | Example 4 | Example 5 |
|---|---|---|---|
| S-1 | 0.778 | — | 1.40 |
| S-2 | — | 1.13 | — |
| SA-9000 | 1.222 | — | — |
| OPE-2St 1200 | — | 0.87 | — |
| OPE-2St-2200 | — | — | 0.60 |
| DCP | 0.02 | 0.02 | — |

| | | |
|---|---|---|
| Curing Condition | 220° C. × 2 hours | 200° C. × 2 hours |

| | | | |
|---|---|---|---|
| Dk@10 GHz | 2.53 | 2.52 | 2.57 |
| Df@10 GHz | 0.0033 | 0.0049 | 0.0017 |

### Examples 6 and 7

In order to confirm the long-term stability of the dielectric properties of the curable resin of the present invention, the test piece obtained in Example 5 was exposed to the accelerated conditions shown in Table 2, and then the dielectric properties were confirmed.

TABLE 2

| | Example 6 | Example 7 |
|---|---|---|
| | Accelerated conditions | |
| | Immersed in 25° C. water × 24 hours | 150° C. × 24 hours |
| Dk@10 GHz | 2.58 | 2.64 |
| Df@10 GHz | 0.0017 | 0.0039 |

As shown in Tables 1 and 2, the dielectric loss tangent (Df) of each of Examples 3 to 7 was 0.005 or less. This value satisfies the required characteristics in Non-Patent Documents 1 and 2.

Table 1 of Patent Document 3 discloses the dielectric loss tangent of a cured product of a resin composition containing a modified phenolic resin, which is a reaction product of a petroleum resin and a dicyclopentadiene-type phenolic resin. Among Examples 1 to 7 and Comparative Example 1 in Table 1 of Patent Document 3, even Example 6, which has the lowest dielectric loss tangent (Df), is 0.006. This confirms that Examples 3 to 7 of the present application, which have a lower dielectric loss tangent than Example 6 of Patent Document 3, have excellent dielectric properties.

The curable resin and the curable resin composition of the present invention are suitably used for electric and electronic parts such as semiconductor encapsulants, printed wiring boards, and build-up laminates.

This application claims priority based on Japanese Patent Application No. 2023-039175, filed on Mar. 14, 2023.

1. A curable resin represented by the following formula (1): 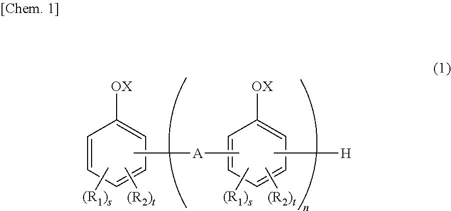
in formula (1), A represents any one of the following formulas (1-a), (1-c), and (1-d),
each of the multiple Xs independently represents any one of the following formulas (1-e) to (1-g),
each of the multiple R₁s independently represents a residue obtained by removing one hydrogen atom from a C9 petroleum resin,
each of the multiple R₂ independently represents a hydrogen atom, a hydrocarbon group having 1 to 10 carbon atoms, an alkoxy group having 1 to 6 carbon atoms, an amino group, or a hydroxy group,
each of the multiple s and t independently represents an integer of 0 to 3, and the sum of s and t is an integer of 0 to 3, s being the number of R₁s bonded to the same aromatic ring, t being the number of R₂ bonded to the same aromatic ring,
the average value sₐᵥₑ of s is 0<sₐᵥₑ≤3, and the average value tₐᵥₑ of t is 0≤tₐᵥₑ≤2,
n is the number of repetitions, and the average value nₐᵥₑ of n is 0.1≤nₐᵥₑ≤5, 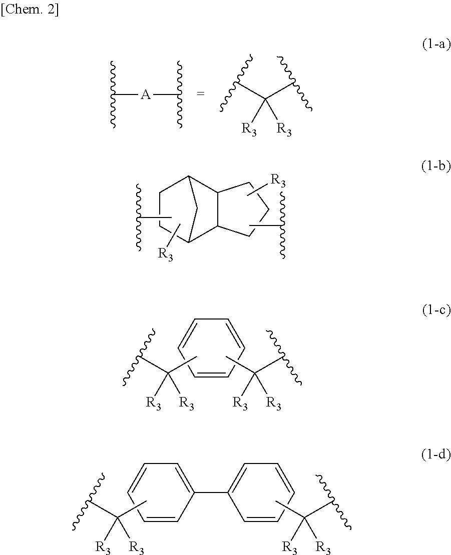
in formulas (1-a) to (1-d), each of the multiple R₃s independently represents a hydrogen atom or a hydrocarbon group having 1 to 10 carbon atoms,
the wavy line represents a bonding site to the aromatic ring in formula (1), 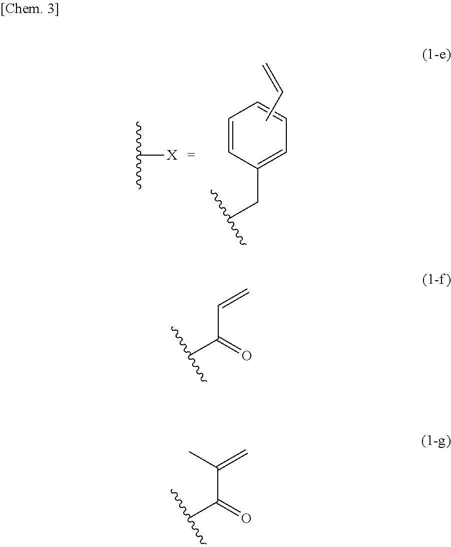
in formulas (1-e) to (1-g), the wavy lines represent the bonding sites to the oxygen atom in formula (1).

2. A curable resin obtained by reacting a phenolic resin obtained by reacting a phenolic resin (P3) containing a C9 petroleum resin (P2) having a phenolic hydroxy group with any of the compounds represented by the following formulas (4-a), (4-c), and (4-d), and a compound represented by any of the following formulas (2-a) to (2-c): 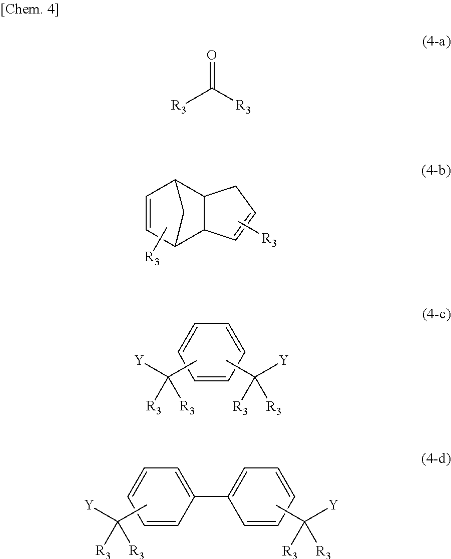
in formulas (4-a) to (4-d), each of the multiple R3 independently represents a hydrogen atom or a hydrocarbon group having 1 to 10 carbon atoms. Each of the multiple Y independently represents a hydrogen atom, a fluorine atom, a chlorine atom, a bromine atom, an iodine atom, a hydroxy group, or an alkoxy group having 1 to 6 carbon atoms, 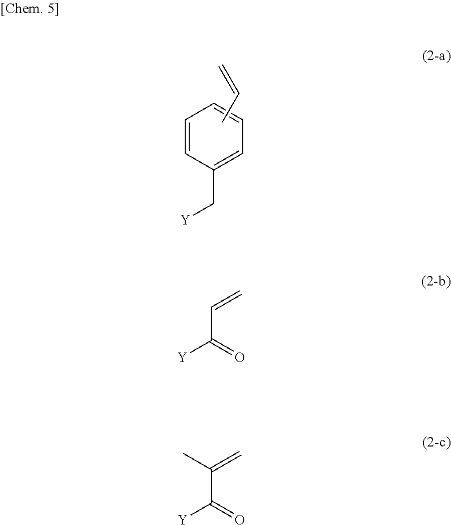
in formulas (2-a) to (2-c), a plurality of Y each independently represent a hydrogen atom, a fluorine atom, a chlorine atom, a bromine atom, an iodine atom, a hydroxy group, or an alkoxy group having 1 to 6 carbon atoms.

3. A curable resin obtained by reacting a phenolic resin obtained by reacting a polyhydroxy resin represented by the following formula (3) with a C9 petroleum resin (P1) having a double bond, with a compound represented by any one of the following formulas (2-a) to (2-c): 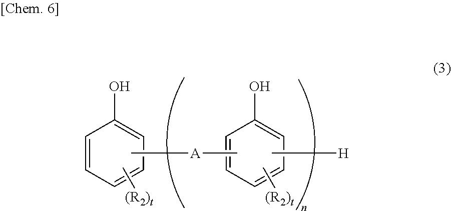
in formula (3), A represents any one of the following formulas (1-a), (1-c), and (1-d), each of the multiple R₂s independently represents a hydrogen atom, a hydrocarbon group having 1 to 10 carbon atoms, an alkoxy group having 1 to 6 carbon atoms, an amino group, or a hydroxy group,
each of the multiple ts independently represents an integer of 0 to 3,
the average value tₐᵥₑ of t is 0≤tₐᵥₑ≤2,
n is the number of repetitions, and the average value nₐᵥₑ of n is 0.1≤nₐᵥₑ≤5, 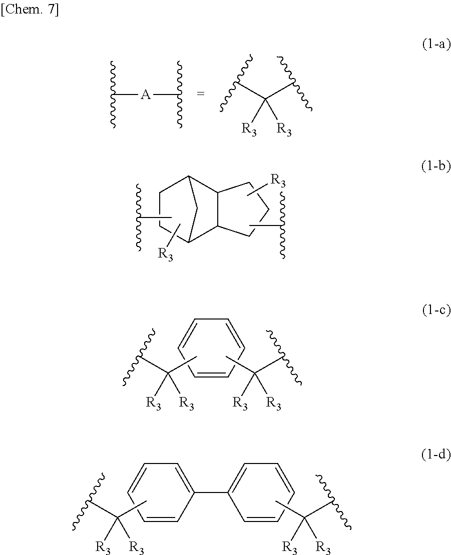
in formulas (1-a) to (1-d), each of the multiple R3s independently represents a hydrogen atom or a hydrocarbon group having 1 to 10 carbon atoms,
the wavy line represents a bonding site to the aromatic ring in formula (3), 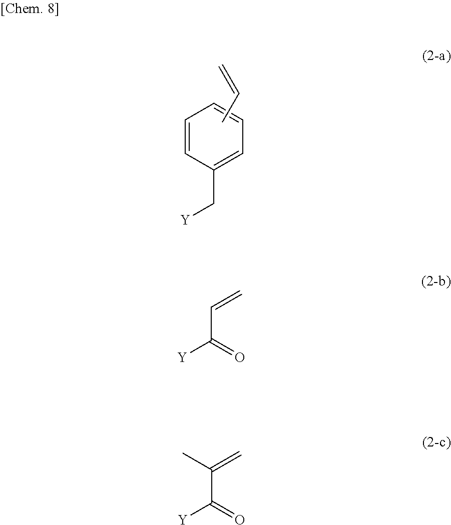
in formulas (2-a) to (2-c), a plurality of Y each independently represent a hydrogen atom, a fluorine atom, a chlorine atom, a bromine atom, an iodine atom, a hydroxy group, or an alkoxy group having 1 to 6 carbon atoms.

4. A curable resin composition comprising the curable resin according to claim 1.

5. The curable resin composition according to claim 4, further comprising a polyphenylene ether resin.

6. The curable resin composition according to claim 4, further comprising a maleimide resin.

7. The curable resin composition according to claim 4, further comprising a polyolefin resin or a polystyrene resin.

8. The curable resin composition according to claim 4, further comprising an inorganic filler.

9. The curable resin composition according to claim 4, further comprising a curing accelerator.

10. The curable resin composition according to claim 4, further comprising a polymerization initiator.

11. A cured product of the curable resin composition according to claim 4.

12. A prepreg obtained by using the curable resin composition according to claim 4.

13. A laminate obtained by curing the curable resin composition according to claim 4.

14. A semiconductor substrate comprising the laminate according to claim 13.

15. A curable resin composition comprising the curable resin according to claim 2.

16. The curable resin composition according to claim 15, further comprising a polyphenylene ether resin.

17. The curable resin composition according to claim 15, further comprising a maleimide resin.

18. A curable resin composition comprising the curable resin according to claim 3.

19. The curable resin composition according to claim 18, further comprising a polyphenylene ether resin.

20. The curable resin composition according to claim 18, further comprising a maleimide resin.
